(19) United States
(12) Patent Application Publication
(10) Pub. No.: US 2025/0105583 A1
(43) Pub. Date: Mar. 27, 2025

(54) SEMICONDUCTOR LIGHT EMITTING DEVICE

(71) Applicant: ROHM CO., LTD., Kyoto-shi (JP)

(72) Inventors: Okimoto KONDO, Kyoto-shi (JP); Tomoichiro TOYAMA, Kyoto-shi (JP)

(21) Appl. No.: 18/893,211

(22) Filed: Sep. 23, 2024

(30) Foreign Application Priority Data
Sep. 25, 2023 (JP) 2023-160241

(51) Int. Cl. H01S 5/0225; H01S 5/02234; H01S 5/026; H01S 5/42

(52) U.S. Cl. CPC H01S 5/0225; H01S 5/02234; H01S 5/0264; H01S 5/423

(57) ABSTRACT

A semiconductor light emitting device includes a surface-emitting laser element including an element front surface from which a laser beam is emitted, a light-transmissive first resin portion that encapsulates the surface-emitting laser element and includes a first resin surface, and a second resin portion that differs from the first resin portion and is at least partially formed on the first resin surface facing the element front surface in a direction orthogonal to the element front surface.

### CROSS-REFERENCE TO RELATED APPLICATIONS

This application is based upon and claims the benefit of priority from prior Japanese Patent Application No. 2023-160241, filed on Sep. 25, 2023, the entire contents of which are incorporated herein by reference.

### BACKGROUND

### 1. Field

The present disclosure relates to a semiconductor light emitting device.

### 2. Description of Related Art

A semiconductor light emitting device including a light emitting diode (LED) as a light source (refer to, for example, Japanese Laid-Open Publication No. 2013-41866) is a known light source device that may be used in various types of electronic devices.

### BRIEF DESCRIPTION OF THE DRAWINGS

FIG. 1 is a schematic perspective view of a semiconductor light emitting device in accordance with a first embodiment.

FIG. 2 is a schematic plan view showing the interior of the semiconductor light emitting device illustrated in FIG. 1.

FIG. 3 is a schematic cross-sectional view of the semiconductor light emitting device taken along line F3-F3 in FIG. 2.

FIG. 4 is a schematic plan view showing a first resin portion and a second resin portion added to the interior of the semiconductor light emitting device illustrated in FIG. 2.

FIG. 5 is a graph illustrating a far field pattern in a semiconductor light emitting device of a comparative example.

FIG. 6 is a graph illustrating a far field pattern in the semiconductor light emitting device in accordance with the first embodiment.

FIG. 7 is a schematic cross-sectional view of a semiconductor light emitting device in accordance with a modified example of the first embodiment.

FIG. 8 is a schematic cross-sectional view of a semiconductor light emitting device in accordance with a second embodiment.

FIG. 9 is a graph illustrating far field patterns in the semiconductor light emitting devices in accordance with the first embodiment and the second embodiment.

FIG. 10 is a schematic cross-sectional view of a semiconductor light emitting device in accordance with a modified example of the second embodiment.

FIG. 11 is a schematic cross-sectional view of a semiconductor light emitting device in accordance with a third embodiment.

FIG. 12 is a schematic cross-sectional view of a semiconductor light emitting device in accordance with a modified example of the third embodiment.

FIG. 13 is a schematic plan view showing the interior of a semiconductor light emitting device in accordance with a fourth embodiment.

FIG. 14 is a schematic cross-sectional view of the semiconductor light emitting device taken along line F14-F14 in FIG. 13.

FIG. 15 is a schematic plan view showing a first resin portion and a second resin portion added to the interior of the semiconductor light emitting device illustrated in FIG. 13.

FIG. 16 is a schematic cross-sectional view of a semiconductor light emitting device in accordance with a first modified example of the fourth embodiment.

FIG. 17 is a schematic cross-sectional view of a semiconductor light emitting device in accordance with a second modified example of the fourth embodiment.

FIG. 18 is a schematic plan view of a semiconductor light emitting device in accordance with a third modified example of the fourth embodiment.

FIG. 19 is a schematic cross-sectional view of the semiconductor light emitting device in accordance with the third modified example taken along line F19-F19 in FIG. 18.

FIG. 20 is a schematic cross-sectional view showing a semiconductor light emitting device in accordance with a modified example.

FIG. 21 is a schematic cross-sectional view showing a semiconductor light emitting device in accordance with a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Several embodiments of a semiconductor light emitting device will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description includes exemplary embodiments of devices, system, and methods in accordance with the present disclosure. This detailed description is illustrative and is not intended to limit embodiments of the present disclosure or the application and use of the embodiments.

In this specification, the phrase “at least one of” as used in this disclosure means “one or more” of a desired choice. As one example, the phrase “at least one of” as used in this disclosure means “only one of the two choices” or “both of the two choices” in a case where the number of choices is two. In another example, the phrase “at least one of” as used in this disclosure means “only one single choice” or “any combination of two or more choices” if the number of its choices is three or more.

In this specification, “the length (particle diameter, dimension) of A is equal to the length (particle diameter, dimension) of B,” or “the length (particle diameter, dimension) of A and the length (particle diameter, dimension) of B are equal” includes, for example, a relationship in which the difference is 10% or less between the length (particle diameter, dimension) of A and the length (particle diameter, dimension) of B.

### First Embodiment

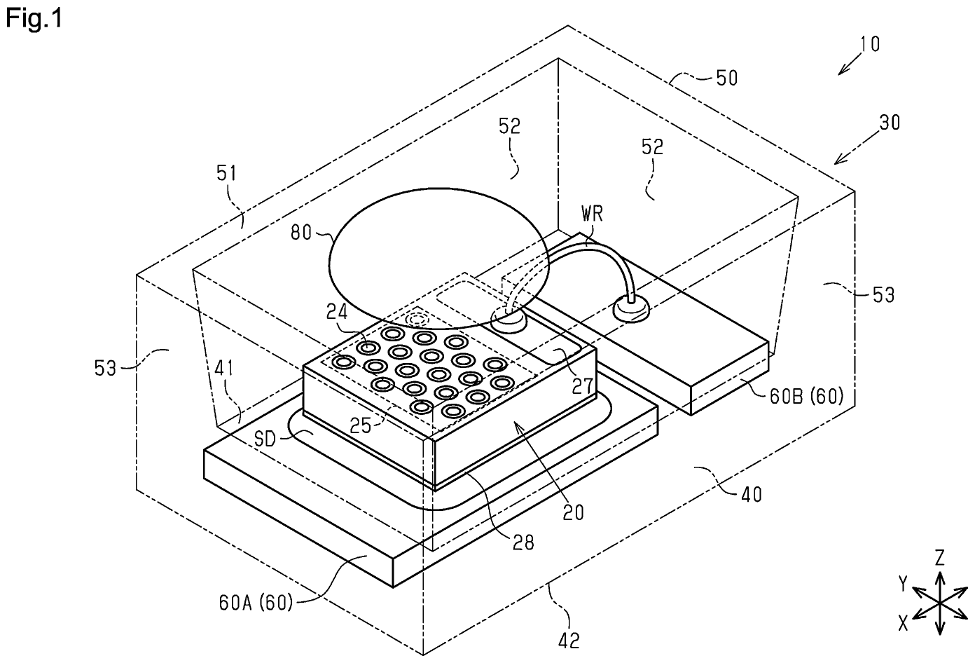

A semiconductor light emitting device 10 according to a first embodiment will now be described with reference to FIGS. 1 to 4.

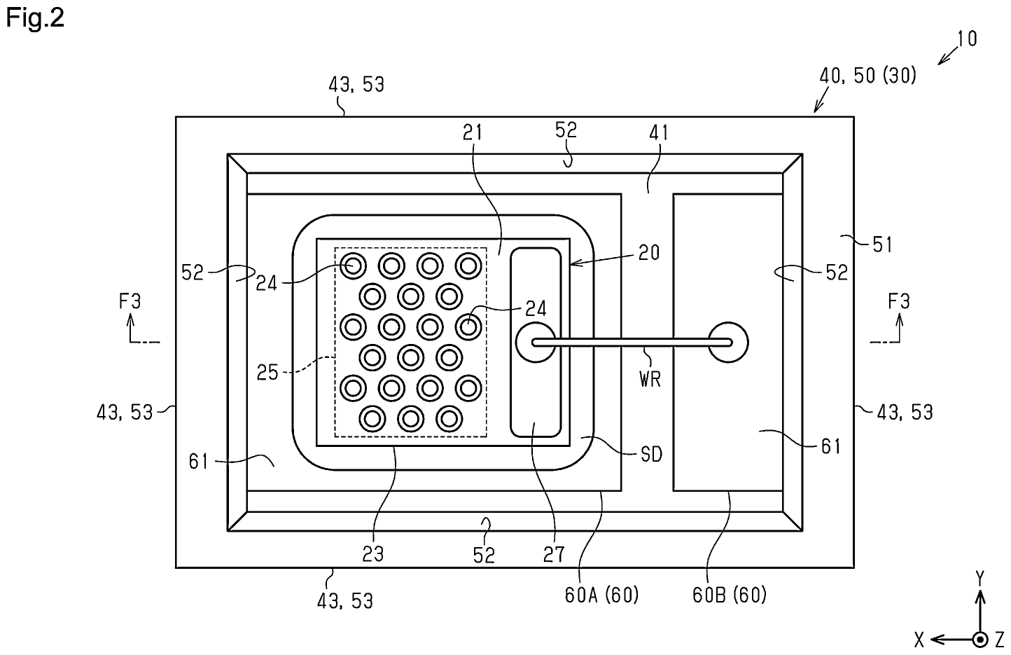

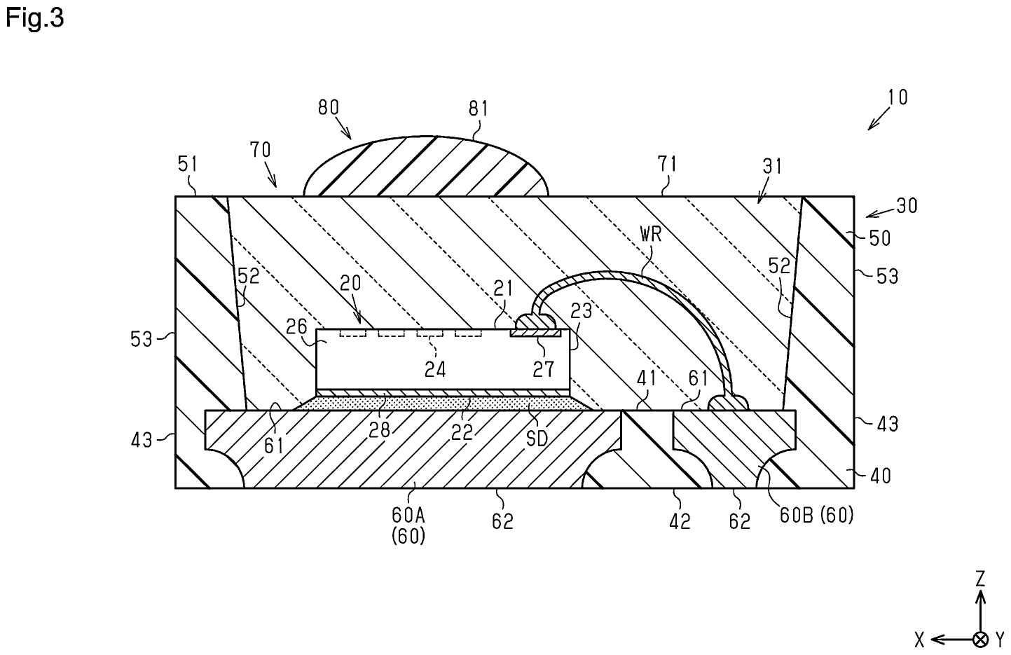

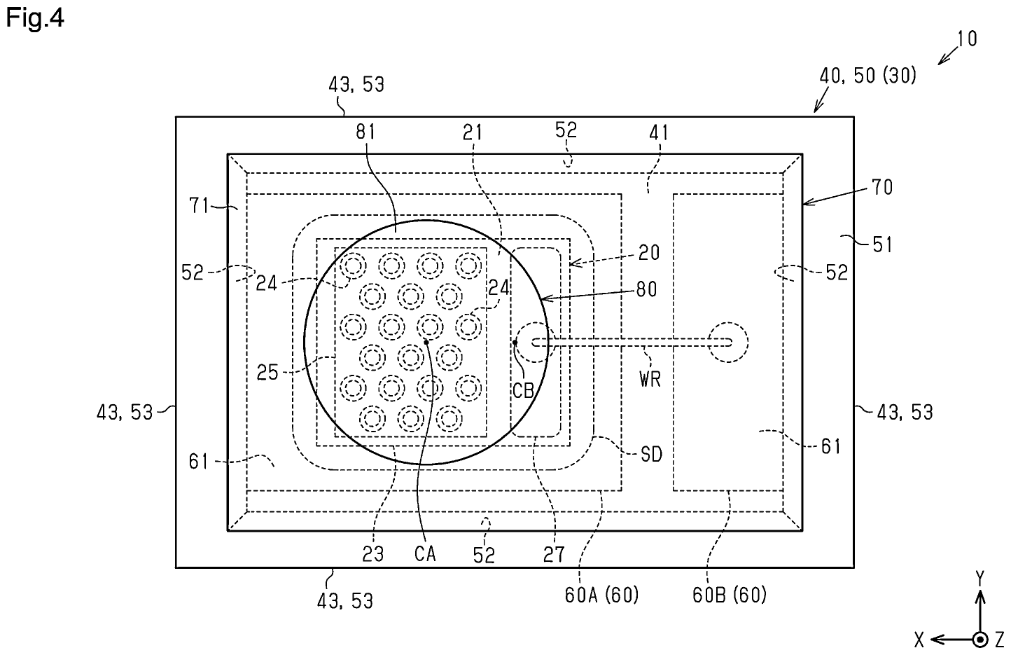

FIG. 1 is a schematic perspective view showing the structure of a semiconductor light emitting device 10 according to the first embodiment. In FIG. 1, to aid understanding of the drawing, an element case 30, which will be described later, is shown by the double-dashed lines, and a first resin portion 70, which will be described later, is not shown. FIG. 2 is a schematic plan view showing the structure of the semiconductor light emitting device 10 of FIG. 1. In FIG. 2, to aid understanding of the drawing, a second resin portion 80, which will be described later, is not shown. FIG. 3 is a schematic cross-sectional view showing the structure of the semiconductor light emitting device 10 taken along line F3-F3 in FIG. 2. FIG. 4 is a schematic plan view showing the structure of FIG. 2 in a state in which the first resin portion 70 and the second resin portion 80 are added. The X-axis, Y-axis, and Z-axis are orthogonal to one another as shown in FIG. 1. The term “plan view” as used in this specification is a view of the semiconductor light emitting device 10 or the elements of the semiconductor light emitting device 10 taken in the Z-direction.

As shown in FIG. 1, the semiconductor light emitting device 10 includes a surface-emitting laser element 20, which serves as a light source, and the element case 30, which accommodates the surface-emitting laser element 20.

The element case 30 includes a bottom wall 40, on which the surface-emitting laser element 20 is arranged, and a peripheral wall 50, which surrounds the surface-emitting laser element 20 in plan view. In one example, the bottom wall 40 and the peripheral wall 50 are formed integrally as an integrated structure. The element case 30 is composed of an insulative material. In one example, the element case 30 is composed of an opaque resin material. In one example, the element case 30 is composed of a black epoxy resin. The element case 30 may be composed of any material.

The bottom wall 40 has the form of a rectangular flat plate of which the thickness direction corresponds to the Z-direction. In one example, the bottom wall 40 is rectangular in plan view, with the X-direction corresponding to the longitudinal direction, and the Y-direction corresponding to the lateral direction. As shown in FIG. 3, the bottom wall 40 includes a bottom wall front surface 41 and a bottom wall back surface 42, which are located at opposite sides in the Z-direction, and four bottom wall side surfaces 43, which connect the bottom wall front surface 41 and the bottom wall back surface 42.

The bottom wall 40 includes terminals 60 extending through the bottom wall 40 in the Z-direction. Each terminal 60 includes a terminal front surface 61, which faces the same direction as the bottom wall front surface 41, and a terminal back surface 62, which faces the same direction as the bottom wall back surface 42. The terminal front surface 61 is exposed from the bottom wall front surface 41. The terminal back surface 62 is exposed from the bottom wall back surface 42. Each terminal 60 is composed of a material containing, for example, copper (Cu), aluminum (Al), or the like. In the first embodiment, each terminal 60 is composed of a material containing Cu. Each terminal 60 is formed by, for example, etching a metal plate containing Cu.

As shown in FIG. 2, the terminals 60 include a first terminal 60A and a second terminal 60B. The first terminal 60A is a terminal on which the surface-emitting laser element 20 is mounted. The second terminal 60B is electrically connected to the surface-emitting laser element 20. The first terminal 60A and the second terminal 60B are located at the same position in the Y-direction and separated from each other in the X-direction. The first terminal 60A is rectangular in plan view, with the X-direction corresponding to its longitudinal direction, and the Y-direction corresponding to its lateral direction. The second terminal 60B is rectangular in plan view, with the Y-direction corresponding to its longitudinal direction, and the X-direction corresponding to its lateral direction.

As shown in FIGS. 1 and 2, the peripheral wall 50 rises from the peripheral portion of the bottom wall 40 in the Z-direction. The peripheral wall 50 has the form of a rectangular frame in plan view. The peripheral wall 50 includes a peripheral wall front surface 51, which faces the same direction as the bottom wall front surface 41, peripheral wall inner surfaces 52, and peripheral wall outer surfaces 53. In one example, as shown in FIG. 3, the peripheral wall outer surfaces 53 are flush with the bottom wall side surfaces 43 of the bottom wall 40. The peripheral wall inner surfaces 52 and the corresponding peripheral wall outer surfaces 53 are located at opposite sides of the peripheral wall 50. The peripheral wall inner surfaces 52 are inclined toward the outer side of the element case 30 from the bottom wall front surface 41 to the peripheral wall front surface 51. The peripheral wall inner surfaces 52 are inclined toward the peripheral wall outer surfaces 53 from the bottom wall front surface 41 to the peripheral wall front surface 51.

The element case 30 includes an accommodation cavity 31 defined by the bottom wall 40 and the peripheral wall 50. The accommodation cavity 31 accommodates the surface-emitting laser element 20. The element case 30 is open in the direction the peripheral wall front surface 51 is facing. In one example, the accommodation cavity 31 has a planar area in a direction orthogonal to the Z-direction that increases as the bottom wall front surface 41 becomes farther.

The surface-emitting laser element 20, which is accommodated in the accommodation cavity 31 of the element case 30, has the form of a rectangular plate of which the thickness direction is the Z-direction. Thus, the Z-direction corresponds to the thickness direction of the surface-emitting laser element 20. The surface-emitting laser element 20 may be a vertical cavity surface-emitting laser (VCSEL) element or a two-dimensional photonic crystal surface-emitting laser element. In one example, the surface-emitting laser element 20 is a VCSEL element.

The surface-emitting laser element 20 includes an element front surface 21 and an element back surface 22, which are located at opposite sides in the Z-direction, and four element side surfaces 23, which connect the element front surface 21 and the element back surface 22. The element front surface 21 faces the same direction as the peripheral wall front surface 51 of the peripheral wall 50 of the element case 30. Thus, the element case 30 is open at the side the element front surface 21 is facing. The Z-direction is orthogonal to the element front surface 21. Thus, a plan view refers to a view taken in the direction orthogonal to the element front surface 21.

The surface-emitting laser element 20 is configured to emit a laser beam from the element front surface 21. The laser beam is emitted from the element front surface 21 in the Z-direction. In one example, as shown in FIG. 2, the surface-emitting laser element 20 includes light emitters 24 formed in the element front surface 21. The light emitters 24 are each configured to emit a laser beam from the element front surface 21 in the Z-direction. The surface-emitting laser element 20 includes a light-emitting region 25 where the light emitters 24 are formed. The light-emitting region 25 is indicated by the broken lines and defined as the region in the element front surface 21 surrounding all of the light emitters 24. The shape of the light-emitting region 25 in plan view is varied in accordance with the arrangement of the light emitters 24. In the example of FIG. 2, the light-emitting region 25 has a rectangular shape in plan view.

As shown in FIG. 3, the surface-emitting laser element 20 includes an element substrate 26. The element substrate 26 may include, for example, a semiconductor substrate containing gallium arsenide (GaAs), and a semiconductor layer on the semiconductor substrate. The semiconductor layer may include a conductive layer and semiconductor layers, such as an active layer and a distributed Bragg reflector (DBR) layer. The light emitters 24 are arranged in the element substrate 26.

As shown in FIG. 2, a front surface electrode 27 is formed in the element front surface 21. The surface-emitting laser element 20 includes a conductive layer arranged in the element substrate 26 and electrically connected to the light emitters 24. The front surface electrode 27 is electrically connected to the conductive layer. The front surface electrode 27 has the form of a strip and extends in the Y-direction in plan view. In one example, the front surface electrode 27 is arranged on the one of the two ends of the element front surface 21 in the X-direction that is closer to the second terminal 60B.

The front surface electrode 27 is electrically connected by a wire WR to the second terminal 60B. The front surface electrode 27 is defined as a region where the wire WR is connected. In the example shown in FIG. 2, the wire WR extends in the X-direction in plan view. The wire WR is, for example, a bonding wire. The wire WR contains at least one of gold (Au), Al, and Cu.

As shown in FIG. 3, a back surface electrode 28 is formed on the element back surface 22. In one example, the back surface electrode 28 is formed over the entire element back surface 22. In one example, the back surface electrode 28 serves as a cathode electrode. In one example, the front surface electrode 27 serves as an anode electrode.

The surface-emitting laser element 20 is mounted on the first terminal 60A. In further detail, the surface-emitting laser element 20 is bonded by conductive bonding material SD to the terminal front surface 61 of the first terminal 60A. This electrically connects the back surface electrode 28 of the surface-emitting laser element 20 to the first terminal 60A with the conductive bonding material SD.

As shown in FIG. 3, the semiconductor light emitting device 10 includes the first resin portion 70 and the second resin portion 80.

The accommodation cavity 31 of the element case 30 is filled with the first resin portion 70. The first resin portion 70 encapsulates the surface-emitting laser element 20 and the wire WR. The first resin portion 70 is composed of a light-transmissive resin material. In one example, the first resin portion 70 is composed of a transparent resin material. The first resin portion 70 includes a first resin surface 71. In the example of FIG. 3, the first resin surface 71 is located at the same position as the peripheral wall front surface 51 of the peripheral wall 50 in the Z-direction. Thus, the first resin portion 70 entirely covers the peripheral wall inner surfaces 52 of the peripheral wall 50.

As shown in FIGS. 3 and 4, the second resin portion 80 is in contact with the first resin surface 71. The second resin portion 80 is selectively arranged on the first resin surface 71. In one example, the second resin portion 80 is separated from a circumferential edge of the first resin surface 71. In other words, the second resin portion 80 is separated from the peripheral wall 50 in plan view.

In one example, the second resin portion 80, which is formed on at least part of the first resin surface 71, faces the surface-emitting laser element 20 in the Z-direction. In the first embodiment, the second resin portion 80 entirely covers the light-emitting region 25 of the surface-emitting laser element 20 in plan view. That is, the second resin portion 80 faces all of the light emitters 24 in plan view.

As shown in FIG. 4, the second resin portion 80 is circular in plan view. The second resin portion 80 is arranged so that the center CA of its circle is offset from the center CB of the element case 30. In one example, the center CA of the second resin portion 80 is offset in the X-direction from the center CB of the element case 30. The center CB of the element case 30 is defined by the intersecting point of the two diagonal lines connecting the four corners of the peripheral wall 50.

The second resin portion 80 includes parts projecting out of the element front surface 21 of the surface-emitting laser element 20 in the Y-direction in plan view. In other words, the diameter of the second resin portion 80 is greater than the lateral direction dimension of the surface-emitting laser element 20. The diameter of the second resin portion 80 is less than the longitudinal direction dimension of the surface-emitting laser element 20. The second resin portion 80 may have any diameter in plan view. Further, the second resin portion 80 may have any shape in plan view.

The second resin portion 80 differs from the first resin portion 70. In one example, the second resin portion 80 is composed of an opaque resin material. In one example, the second resin portion 80 is composed of a resin material having a higher light reflectance than the first resin portion 70. That is, the second resin portion 80 is formed by a reflector. In the first embodiment, the second resin portion 80 is composed of a white resin material serving as the reflector. The white resin material may be, for example, an epoxy resin in which titanium oxide or silica is mixed.

As shown in FIG. 3, the second resin portion 80 is curved outward and away from the first resin surface 71. The second resin portion 80 includes a second resin surface 81. The second resin surface 81 differs from the surface contacting the first resin surface 71. The second resin surface 81 is curved outward and away from the first resin surface 71 in the Z-direction.

In the example shown in FIG. 3, the second resin portion 80 and the bottom wall 40 are located at opposite sides of the peripheral wall front surface 51 of the peripheral wall 50 in the Z-direction. That is, the second resin surface 81 and the bottom wall 40 are located at opposite sides of the peripheral wall front surface 51 in the Z-direction.

### Operation of First Embodiment

The operation of the semiconductor light emitting device 10 in accordance with the first embodiment will now be described.

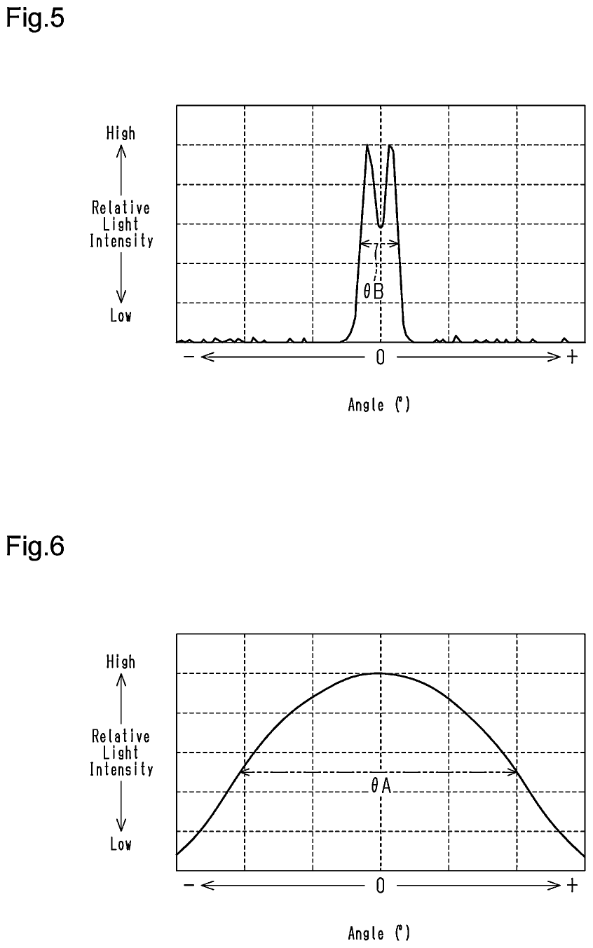

FIGS. 5 and 6 illustrate far-field pattern (FFP) data indicating the laser beam emission pattern characteristic of the semiconductor light emitting device 10. The far-field pattern is data indicating the relationship between the spreading angle and the relative light intensity of the laser beam. FIG. 5 shows the FFP data collected from a semiconductor light emitting device of a comparative example from which the second resin portion 80 is omitted. FIG. 6 illustrates the FFP data collected from the semiconductor light emitting device 10 in accordance with the first embodiment. In FIGS. 5 and 6, the horizontal axis represents angle, and the vertical axis represents relative light intensity. In FIG. 6, the reference angle (0°) is the position where the light intensity of the laser beam is maximum. In FIG. 5, the FFP data collected from the semiconductor light emitting device of the comparative example is illustrated at an angular position corresponding to the FFP data collected from the semiconductor light emitting device 10 of the first embodiment. The spreading angle of the laser beam is illustrated as an angular range in which the light intensity is, for example, one-half of the maximum light intensity or greater.

As shown in FIG. 5, in the semiconductor light emitting device of the comparative example, at the light-emitting region 25 of the surface-emitting laser element 20, the relative light intensity increases prominently but the spreading angle θB of the laser beam is small. Thus, the semiconductor light emitting device of the comparative example emits a local laser beam from only the light-emitting region 25.

In the semiconductor light emitting device 10 of the first embodiment, the laser beam emitted from the surface-emitting laser element 20 is reflected by the second resin portion 80. The laser beam reflected by the second resin portion 80 is reflected again by the elements of the semiconductor light emitting device 10, such as, for example, the first terminal 60A, the second terminal 60B, and the wire WR. The reflected laser beam is emitted through the first resin portion 70 and from around the second resin portion 80 out of the semiconductor light emitting device 10. Thus, as shown in FIG. 6, the spreading angle θA of the laser beam emitted from the semiconductor light emitting device 10 is increased.

### Advantages of First Embodiment

The semiconductor light emitting device 10 of the first embodiment has the advantages described below.
(1-1) The semiconductor light emitting device 10 includes the surface-emitting laser element 20 including the element front surface 21 from which the laser beam is emitted, the light-transmissive first resin portion 70 encapsulating the surface-emitting laser element 20 and including the first resin surface 71, and the second resin portion 80 differing from the first resin portion 70 and at least partially formed on the first resin surface 71 facing the element front surface 21 in the Z-direction.

With this structure, the laser beam emitted from the surface-emitting laser element 20 and out of the semiconductor light emitting device 10 is affected by the first resin portion 70 and the second resin portion 80, which differs from the first resin portion 70. Thus, the first resin portion 70 and the second resin portion 80 improve the emission pattern characteristic of the laser beam emitted from the semiconductor light emitting device 10.
(1-2) The second resin portion 80 has a higher light reflectance than the first resin portion 70.

With this structure, the laser beam emitted from the surface-emitting laser element 20 is reflected by the second resin portion 80. This reduces local increases in the relative light intensity of the laser beam emitted from the semiconductor light emitting device 10, while increasing the spreading angle of the laser beam.
(1-3) The second resin portion 80 is formed by a reflector.

With this structure, the laser beam emitted from the surface-emitting laser element 20 is readily reflected by the second resin portion 80. This further reduces local increases in the relative light intensity of the laser beam emitted from the semiconductor light emitting device 10, while increasing the spreading angle of the laser beam.
(1-4) The second resin portion 80 is selectively arranged on the first resin surface 71 of the first resin portion 70.

With this structure, the laser beam emitted from the surface-emitting laser element 20 is reflected by the second resin portion 80 and then emitted out of the semiconductor light emitting device 10 from the part of the first resin portion 70 where the second resin portion 80 is not arranged. This reduces local increases in the relative light intensity of the laser beam emitted from the semiconductor light emitting device 10, while increasing the spreading angle of the laser beam.
(1-5) The second resin portion 80 is separated from the circumferential edge of the first resin surface 71 of the first resin portion 70.

With this structure, the laser beam emitted from the surface-emitting laser element 20 is reflected by the second resin portion 80 and then emitted out of the semiconductor light emitting device 10 from at least the circumferential portion of the first resin surface 71 of the first resin portion 70. This reduces local increases in the relative light intensity of the laser beam emitted from the semiconductor light emitting device 10, while increasing the spreading angle of the laser beam.
(1-6) The surface-emitting laser element 20 includes the light emitters 24 arranged in the element front surface 21. The second resin portion 80 faces all of the light emitters 24 in plan view.

With this structure, the laser beam emitted from all of the light emitters 24 of the surface-emitting laser element 20 is reflected by the second resin portion 80. This further reduces local increases in the relative light intensity of the laser beam emitted from the semiconductor light emitting device 10.

### Modified Example of First Embodiment

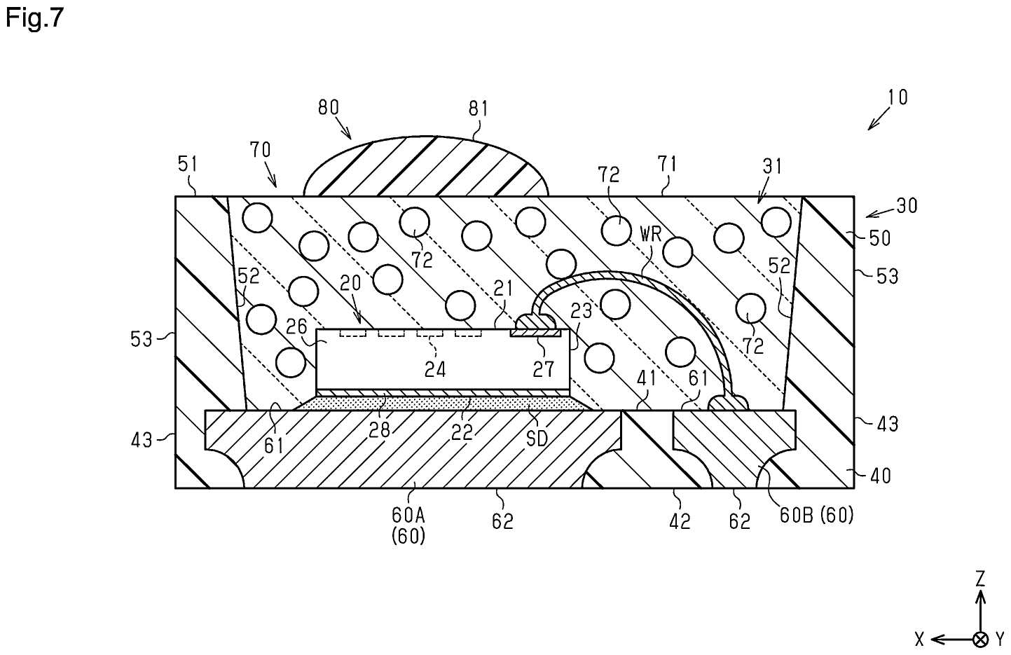

The semiconductor light emitting device 10 in accordance with the first embodiment may be modified as described below. FIG. 7, which shows a modified example of the semiconductor light emitting device 10 in accordance with the first embodiment, is a schematic cross-sectional view of the modified example of the semiconductor light emitting device 10 taken along the same position as line F3-F3 in FIG. 2.

As shown in FIG. 7, the first resin portion 70 contains diffusers 72. The diffusers 72 are fine particles that diffuse light and are dispersed in the first resin portion 70. The diffusers 72 reflect (scatter) light in the first resin portion 70 at the interface of the resin and the diffusers 72 to diffuse light inside the first resin portion 70. The diffusers 72 act to diffuse the laser beam emitted from the element front surface 21 of the surface-emitting laser element 20 in the first resin portion 70 to increase the directivity of the laser beam emitted from the first resin portion 70.

Although not particularly limited, the material of the diffusers 72 may be, for example, silica or other types of glass material. In one example, spherical silica fillers are used as the diffusers 72. Although not particularly limited, the particle diameter of the diffusers 72 is selected to be, for example, small enough with respect to the wavelength of the laser beam emitted from the surface-emitting laser element 20 so that diffusion occurs dominantly.

The diffusers 72 are mixed into the first resin portion 70 at a predetermined compound ratio. In one example, the diffusers 72 are uniformly dispersed in the first resin portion 70. Although the compound ratio of the diffusers 72 in the first resin portion 70 is not particularly limited, the compound ratio should be greater than 0% and less than 100%. A greater compound ratio of the diffusers 72 increases the laser beam directivity angle of the surface-emitting laser element 20. Further, the upper limit of the compound ratio of the diffusers 72 is limited to a predetermined value to avoid large decreases in the output and emission intensity of the laser beam of the semiconductor light emitting device 10.

In one example, the diffusers 72, for example, have a smaller coefficient of linear expansion than the first resin portion 70. In this structure, in comparison with when the first resin portion 70 is composed of only resin, the diffusers 72 reduce the thermal stress applied to the first resin portion 70. Thus, breakage of the wire WR caused by thermal stress on the first resin portion 70 does not occur.

### Second Embodiment

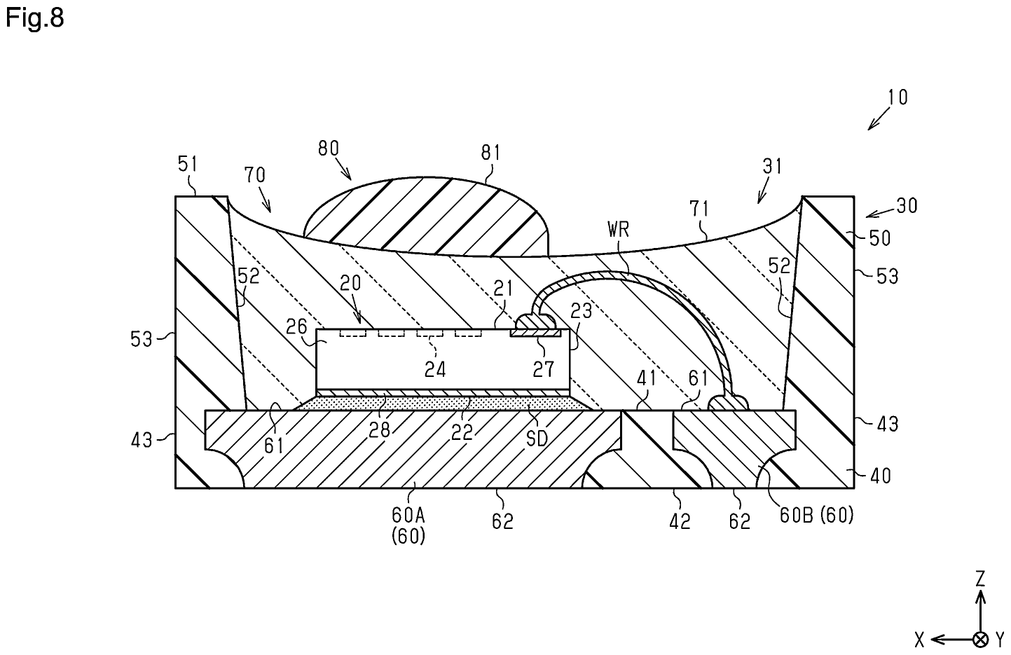

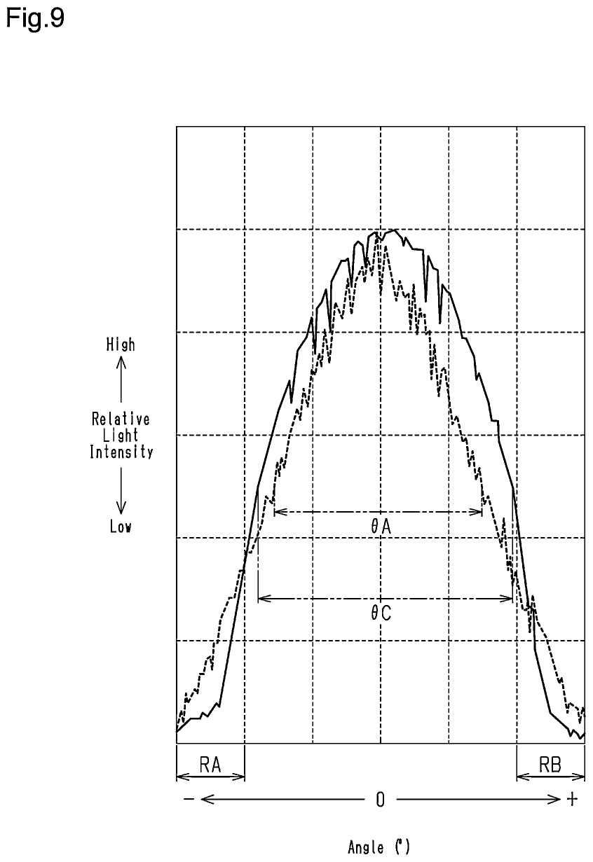

With reference to FIGS. 8 and 9, a semiconductor light emitting device 10 in accordance with a second embodiment will now be described. The semiconductor light emitting device 10 of the second embodiment mainly differs from the semiconductor light emitting device 10 of the first embodiment in the shape of the first resin surface 71 of the first resin portion 70. The description hereafter will focus on the differences from the first embodiment. The same reference characters are given to those components that are the same as the corresponding components of the first embodiment. Such components will not be described in detail.

FIG. 8, which shows the semiconductor light emitting device 10 of the second embodiment, is a schematic cross-sectional view showing the semiconductor light emitting device 10 of the second embodiment taken along the same position as line F3-F3 in FIG. 2.

As shown in FIG. 8, the first resin surface 71 of the first resin portion 70 is curved inward and toward the surface-emitting laser element 20. In other words, the first resin surface 71 is a curved recess that is curved inward in the element case 30 from the peripheral wall front surface 51 of the peripheral wall 50 toward the bottom wall 40. That is, the first resin portion 70 has a thickness that decreases toward the surface-emitting laser element 20. The thickness of the first resin portion 70 is the distance in the Z-direction between the bottom wall front surface 41 of the bottom wall 40 and the first resin surface 71.

The second resin portion 80, which is arranged on the first resin surface 71, has the same shape as the second resin portion 80 in the first embodiment. The positional relationship of the second resin portion 80 and the surface-emitting laser element 20 in plan view is the same as the first embodiment. The positional relationship of the second resin portion 80 and the surface-emitting laser element 20 in the Z-direction differs from the first embodiment. More specifically, the second resin portion 80 is located closer to the surface-emitting laser element 20 in the Z-direction than the first embodiment. The surface of the second resin portion 80 contacting the first resin surface 71 is located closer to the surface-emitting laser element 20 than the peripheral wall front surface 51 of the peripheral wall 50. In the example shown in FIG. 8, part of the second resin portion 80 is located in the Z-direction closer to the surface-emitting laser element 20 than the peripheral wall front surface 51. In other words, the second resin surface 81 of the second resin portion 80 includes a part that is located in the Z-direction closer to the surface-emitting laser element 20 than the peripheral wall front surface 51 and a part that is projected in the Z-direction from the peripheral wall front surface 51 away from the bottom wall 40.

FIG. 9 shows the FFP data collected from the semiconductor light emitting device 10 of the first embodiment and the FFP data collected from the semiconductor light emitting device 10 of the second embodiment. The FFP data of the first embodiment is shown by the graph of the broken lines in FIG. 9. The FFP data of the second embodiment is shown by the graph of the solid lines in FIG. 9. The FFP data of the second embodiment shows angular position using the FFP data of the first embodiment as a reference.

As shown in FIG. 9, the spreading angle θC of the laser beam emitted from the semiconductor light emitting device 10 of the second embodiment is greater than that of the first embodiment. In peripheral regions RA and RB at the two ends where the angle is greater than the reference position (0°), the light intensity of the semiconductor light emitting device 10 of the second embodiment is less than the semiconductor light emitting device 10 of the first embodiment. Thus, the semiconductor light emitting device 10 of the second embodiment has an emission pattern characteristic in which the spreading angle θC is greater, and the light intensity at the peripheral regions RA and RB is less, than the semiconductor light emitting device 10 of the first embodiment.

In this manner, the emission pattern characteristic of the semiconductor light emitting device 10 is obtained by the first resin portion 70 and the second resin portion 80. The shape of the first resin portion 70, for example, the shape of the first resin surface 71, the location of the second resin portion 80, and the like, improve given emission pattern characteristics of the laser beam emitted from the semiconductor light emitting device 10 to the desired characteristics.

### Advantages of Second Embodiment

The semiconductor light emitting device 10 of the second embodiment has the advantages described below.
(2-1) The first resin surface 71 of the first resin portion 70 is curved inward and toward the surface-emitting laser element 20.

With this structure, the laser beam emitted from the semiconductor light emitting device 10 has a greater spreading angle than the semiconductor light emitting device 10 of the first embodiment. In the peripheral regions RA and RB (refer to FIG. 9) at the two ends where the angle is greater than the reference position (0°), the light intensity of the laser beam is less than that of the semiconductor light emitting device 10 of the first embodiment. In this manner, the shape of the first resin surface 71 is changed to vary the emission pattern characteristic.
(2-2) Part of the second resin portion 80 in the Z-direction is located closer to the surface-emitting laser element 20 than the peripheral wall front surface 51.

With this structure, in comparison with when the second resin portion 80 is entirely located at the side of the peripheral wall front surface 51 facing away from the surface-emitting laser element 20, the semiconductor light emitting device 10 may be decreased in height.

### Modified Example of Second Embodiment

The semiconductor light emitting device 10 of the second embodiment may be modified, for example, as described below.

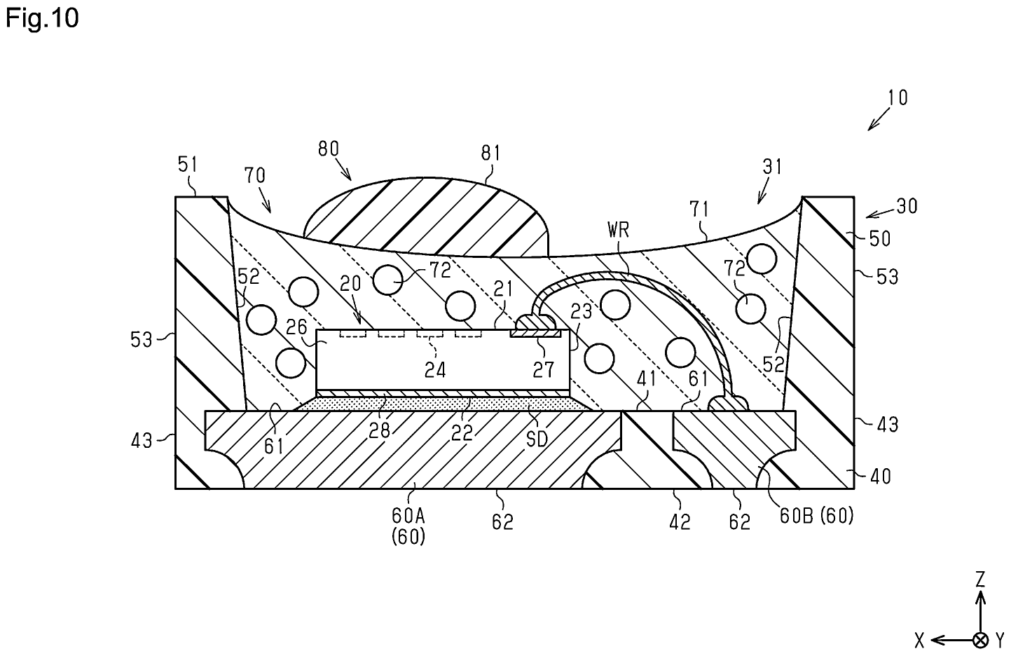

The first resin portion 70 may be modified to have any structure. The semiconductor light emitting device 10 of such a modified example will now be described with reference to FIG. 10. FIG. 10, which shows a modified example of the semiconductor light emitting device 10 in accordance with the second embodiment, is a schematic cross-sectional view of the modified example of the semiconductor light emitting device 10 taken along the same position as line F3-F3 in FIG. 2.

As shown in FIG. 10, the first resin portion 70 contains diffusers 72. The diffusers 72 are fine particles that diffuse light and are dispersed in the first resin portion 70. The diffusers 72 reflect (scatter) light in the first resin portion 70 at the interface of the resin and the diffusers 72 to diffuse light inside the first resin portion 70. The diffusers 72 act to diffuse the laser beam emitted from the element front surface 21 of the surface-emitting laser element 20 in the first resin portion 70 to increase the directivity of the laser beam emitted from the first resin portion 70. The diffusers 72, for example, correspond to the diffusers 72 of the modified example of the semiconductor light emitting device 10 in accordance with the first embodiment shown in FIG. 7.

The second resin surface 81 of the second resin portion 80 may entirely be arranged closer to the surface-emitting laser element 20 than the peripheral wall front surface 51 of the peripheral wall 50 is. This allows the semiconductor light emitting device 10 to be further decreased in height.

The first resin surface 71 of the first resin portion 70 may include a part that is curved inward and toward the surface-emitting laser element 20 and a flat surface that is orthogonal to the Z-direction. The flat surface may be formed, for example, in the part of the first resin surface 71 facing the surface-emitting laser element 20 in the Z-direction.

### Third Embodiment

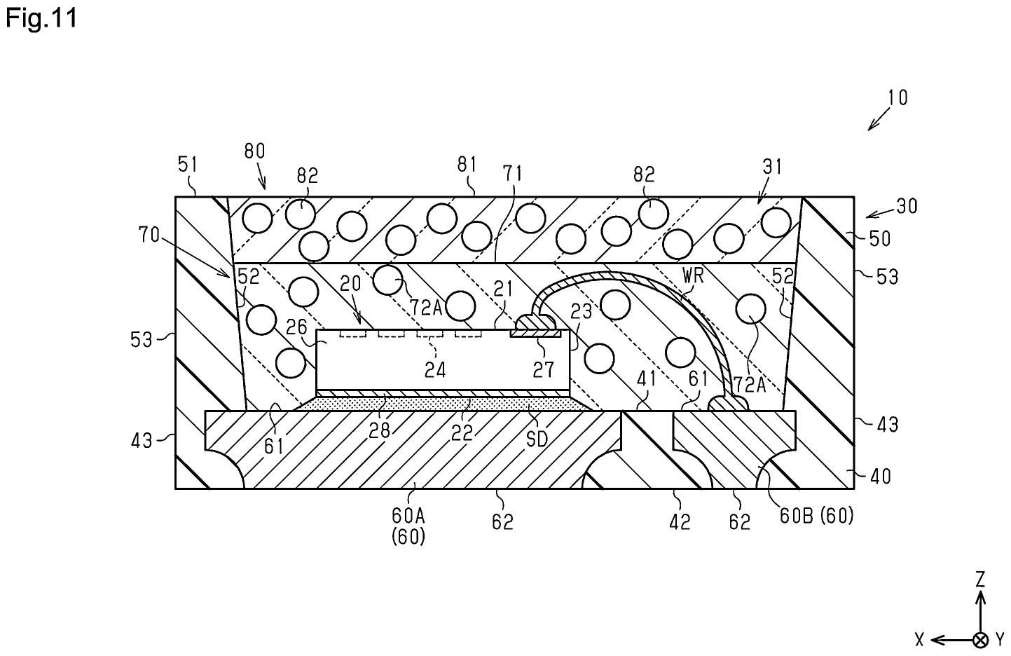

With reference to FIG. 11, a semiconductor light emitting device 10 in accordance with a third embodiment will now be described. The semiconductor light emitting device 10 of the third embodiment mainly differs from the semiconductor light emitting device 10 of the first embodiment in the structure of the first resin portion 70 and the second resin portion 80. The description hereafter will focus on the differences from the first embodiment. The same reference characters are given to those components that are the same as the corresponding components of the first embodiment. Such components will not be described in detail.

As shown in FIG. 11, the first resin portion 70 encapsulates the surface-emitting laser element 20 and the wire WR. The first resin surface 71 of the first resin portion 70 is located closer to the bottom wall 40 of the element case 30 than the peripheral wall front surface 51 of the peripheral wall 50. Thus, the first resin portion 70 covers the part of each peripheral wall inner surface 52 of the peripheral wall 50 that is located toward the bottom wall 40. In the same manner as the first embodiment, the first resin portion 70 is composed of a light-transmissive resin material. In one example, the first resin portion 70 is composed of a transparent resin material.

The first resin portion 70 contains first diffusers 72A. In one example, the first diffusers 72A have the same structure as the diffusers 72 in the first resin portion 70 of the modified example of the first embodiment shown in FIG. 7.

The second resin portion 80 entirely covers the first resin surface 71 of the first resin portion 70. Thus, the second resin portion 80 covers the part of each peripheral wall inner surface 52 of the peripheral wall 50 that projects from the first resin portion 70.

The second resin portion 80 is composed of a light-transmissive resin material. In one example, the second resin portion 80 is composed of a transparent resin material. In the third embodiment, the resin material of the second resin portion 80 is the same as that of the first resin portion 70.

The second resin portion 80 contains second diffusers 82. The second diffusers 82 are fine particles that diffuse light and are dispersed in the second resin portion 80. The second diffusers 82 reflect (scatter) light in the second resin portion 80 at the interface of the resin and the second diffusers 82 to diffuse light inside the second resin portion 80. The second diffusers 82 act to further diffuse the laser beam emitted from the first resin portion 70 in the second resin portion 80 to increase the directivity angle of the laser beam emitted from the second resin portion 80.

Although not particularly limited, the material of the second diffusers 82 may be, for example, silica or other types of glass material. In one example, spherical silica fillers are used as the second diffusers 82. Although not particularly limited, the particle diameter of the second diffusers 82 is selected to be, for example, small enough with respect to the wavelength of the laser beam emitted from the surface-emitting laser element 20 so that diffusion occurs dominantly. In one example, the second diffusers 82 are composed of the same material as the first diffusers 72A.

The second diffusers 82 are mixed into the second resin portion 80 at a predetermined compound ratio. In one example, the second diffusers 82 are uniformly dispersed in the second resin portion 80. Although the compound ratio of the second diffusers 82 in the second resin portion 80 is not particularly limited, the compound ratio should be greater than 0% and less than 100%. A greater compound ratio of the second diffusers 82 increases the laser beam directivity angle of the surface-emitting laser element 20. Further, the upper limit of the compound ratio of the second diffusers 82 is limited to a predetermined value to avoid large decreases in the output and emission intensity of the laser beam of the semiconductor light emitting device 10.

The second resin portion 80 differs from the first resin portion 70. In the third embodiment, the compound ratio of the first diffusers 72A in the first resin portion 70 differs from the compound ratio of the second diffusers 82 in the second resin portion 80. More specifically, the concentration of the second diffusers 82 in the second resin portion 80 is greater than the concentration of the first diffusers 72A in the first resin portion 70. In one example, the concentration of the second diffusers 82 in the second resin portion 80 in percent by weight is greater than that of the first diffusers 72A in the first resin portion 70. In the third embodiment, the particle diameter of the second diffusers 82 is equal to the particle diameter of the first diffusers 72A. In one example, the first diffusers 72A and the second diffusers 82 use the same silica filler. The quantity of the second diffusers 82 per unit volume is greater than that of the first diffusers 72A.

### Advantages of Third Embodiment

The semiconductor light emitting device 10 of the third embodiment has the advantages described below.
(3-1) The first resin portion 70 contains the first diffusers 72A. The second resin portion 80 contains the second diffusers 82. The concentration of the second diffusers 82 in the second resin portion 80 is greater than the concentration of the first diffusers 72A in the first resin portion 70.

With this structure, the laser beam emitted from the surface-emitting laser element 20 is more readily diffused in the second resin portion 80, which is located at the laser beam emission side of the semiconductor light emitting device 10, than in the first resin portion 70. This increases the spreading angle of the laser beam emitted from the semiconductor light emitting device 10.
(3-2) The second resin portion 80 entirely covers the first resin surface 71 of the first resin portion 70.

With this structure, the laser beam of the surface-emitting laser element 20 entirely passes through the second resin portion 80 before being emitted out of the semiconductor light emitting device 10. This increases the spreading angle of the laser beam emitted from the semiconductor light emitting device 10.

### Modified Example of Third Embodiment

The semiconductor light emitting device 10 of the third embodiment may be modified, for example, as described below.

The first resin portion 70 may be modified to have any structure. In one example, the first diffusers 72A may be omitted from the first resin portion 70.

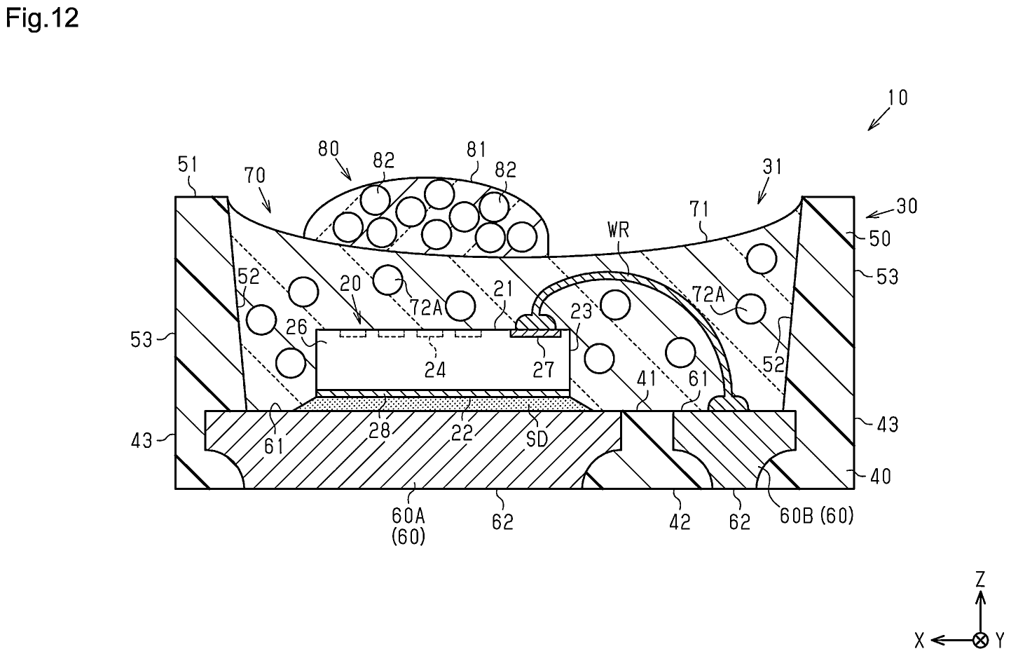

The second resin portion 80 may be modified to have any structure. The semiconductor light emitting device 10 of such a modified example will now be described with reference to FIG. 12. FIG. 12, which shows a modified example of the semiconductor light emitting device 10 in accordance with the third embodiment, is a schematic cross-sectional view of the modified example of the semiconductor light emitting device 10 taken along the same position as line F3-F3 in FIG. 2.

As shown in FIG. 12, the second resin portion 80 is selectively arranged on the first resin surface 71 of the first resin portion 70. The second resin portion 80 is separated from the circumferential edge of the first resin surface 71. The second resin portion 80 has, for example, the same shape and size as the second resin portion 80 of the first embodiment.

In the same manner as the third embodiment, the second resin portion 80 is composed of a light-transmissive resin material. In one example, the second resin portion 80 is composed of a transparent resin material. Further, in the same manner as the third embodiment, the second resin portion 80 contains the second diffusers 82. The second diffusers 82 have, for example, the same structure and size as the second diffusers 82 of the third embodiment.

As apparent from FIG. 12, the compound ratio of the first diffusers 72A in the first resin portion 70 differs from the compound ratio of the second diffusers 82 in the second resin portion 80. More specifically, the concentration of the second diffusers 82 in the second resin portion 80 is greater than the concentration of the first diffusers 72A in the first resin portion 70. In one example, the concentration of the second diffusers 82 in the second resin portion 80 in percent by weight is greater than that of the first diffusers 72A in the first resin portion 70.

In the modified example of the semiconductor light emitting device 10 shown in FIG. 12, the first resin portion 70 may be modified to have any shape. In one example, in the same manner as the first embodiment, the first resin surface 71 of the first resin portion 70 may be located in the Z-direction at the same position as the peripheral wall front surface 51 of the peripheral wall 50. In this case, the second resin portion 80 is located at the side of the peripheral wall front surface 51 facing away from the surface-emitting laser element 20 in the Z-direction. Further, in the modified example of the semiconductor light emitting device 10 shown in FIG. 12, the first diffusers 72A may be omitted from the first resin portion 70.

### Fourth Embodiment

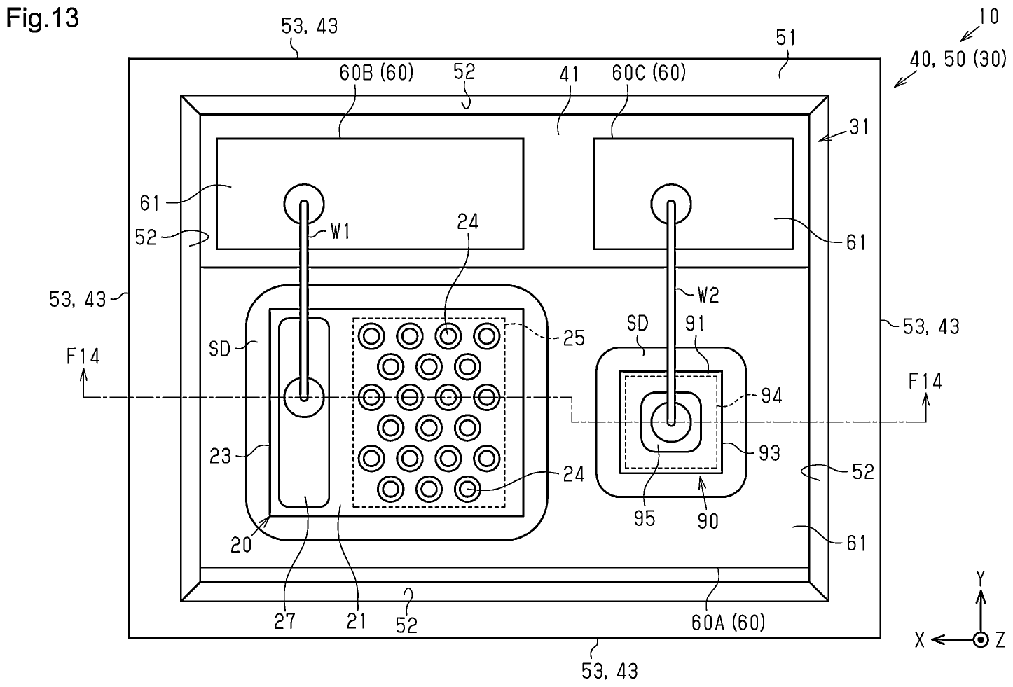

With reference to FIGS. 13 to 15, a semiconductor light emitting device 10 in accordance with a fourth embodiment will now be described. The semiconductor light emitting device 10 of the fourth embodiment mainly differs from the semiconductor light emitting device 10 of the first embodiment in the structure of the terminals 60 and the arrangement of a light-receiving element 90. The description hereafter will focus on the differences from the first embodiment. The same reference characters are given to those components that are the same as the corresponding components of the first embodiment. Such components will not be described in detail.

As shown in FIG. 13, the terminals 60 include first to third terminals 60A to 60C. The second terminal 60B and the third terminal 60C are separated from the first terminal 60A in the Y-direction. The second terminal 60B and the third terminal 60C are located at the same position in the Y-direction and separated from each other in the X-direction. The second terminal 60B and the third terminal 60C both overlap the first terminal 60A as viewed in the Y-direction.

In the semiconductor light emitting device 10, the surface-emitting laser element 20 and the light-receiving element 90 are both accommodated in the accommodation cavity 31 of the element case 30. The light-receiving element 90 is separated from the surface-emitting laser element 20 in the X-direction. The X-direction is one example of a first direction that intersects a direction orthogonal to the element front surface 21 of the surface-emitting laser element 20.

The surface-emitting laser element 20 and the light-receiving element 90 are both mounted on the first terminal 60A. The second terminal 60B is located in the X-direction at a position corresponding to the surface-emitting laser element 20. The third terminal 60C is located in the X-direction at a position corresponding to the light-receiving element 90.

The surface-emitting laser element 20 is arranged so that the front surface electrode 27 is opposite to the light-receiving element 90 in the X-direction. A first wire W1 is connected to the front surface electrode 27. The front surface electrode 27 is electrically connected by the first wire W1 to the second terminal 60B. In the example shown in FIG. 13, the first wire W1 extends in the Y-direction in plan view. The first wire W1 is, for example, a bonding wire. The first wire W1 contains at least one of Au, Al, and Cu.

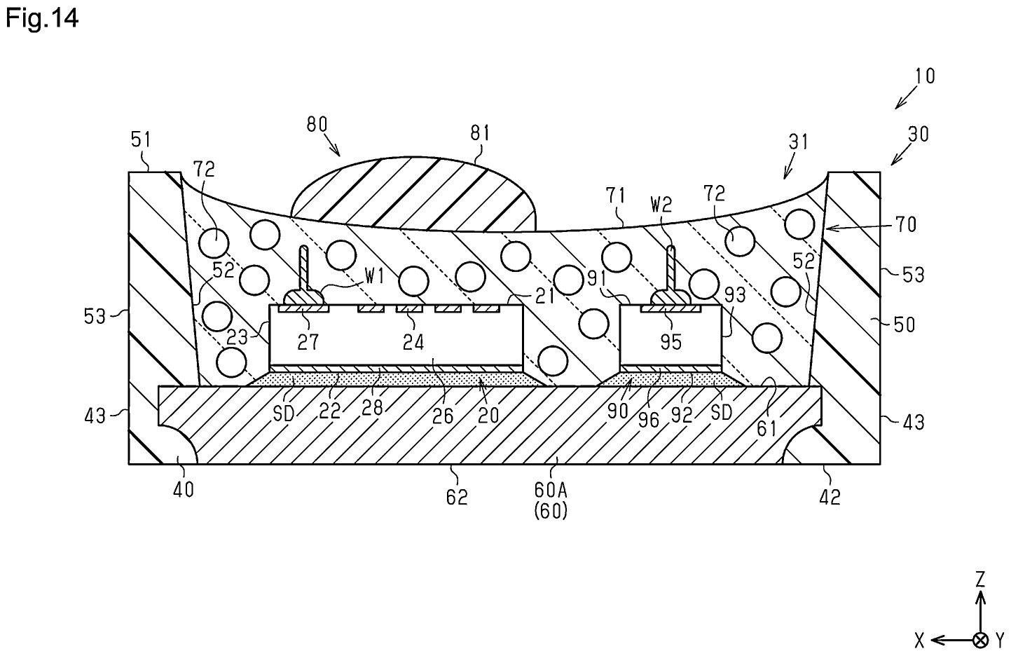

As shown in FIG. 14, in the same manner as the first embodiment, the surface-emitting laser element 20 is bonded by the conductive bonding material SD to the terminal front surface 61 of the first terminal 60A. This electrically connects the back surface electrode 28 of the surface-emitting laser element 20 to the first terminal 60A with the conductive bonding material SD.

As shown in FIGS. 13 and 14, the light-receiving element 90 has the form of a rectangular plate of which the thickness direction is the Z-direction. The light-receiving element 90 includes a light-receiving front surface 91 and a light-receiving back surface 92, which are located at opposite sides in the Z-direction, and a light-receiving side surface 93, which connects the light-receiving front surface 91 and the light-receiving back surface 92. The light-receiving element 90 is, for example, a photodiode.

The light-receiving front surface 91 faces the same direction as the element front surface 21 of the surface-emitting laser element 20. The light-receiving front surface 91 includes a light-receiving region 94 and a front surface electrode 95. The front surface electrode 95, for example, overlaps the light-receiving region 94 in plan view.

The front surface electrode 95 is electrically connected by a second wire W2 to the third terminal 60C. In the example shown in FIG. 13, the second wire W2 extends in the Y-direction in plan view. The second wire W2 is, for example, a bonding wire. The second wire W2 contains at least one of Au, Al, and Cu. The second wire W2 may be composed of, for example, the same material as the first wire W1.

As shown in FIG. 14, the light-receiving back surface 92 faces the same direction as the element back surface 22 of the surface-emitting laser element 20. A back surface electrode 96 is formed on the light-receiving back surface 92. In one example, the back surface electrode 96 is formed over the entire light-receiving back surface 92. In one example, the back surface electrode 96 serves as a cathode electrode. In one example, the front surface electrode 95 serves as an anode electrode.

The light-receiving element 90 is bonded by the conductive bonding material SD to the terminal front surface 61 of the first terminal 60A. This electrically connects the back surface electrode 96 of the light-receiving element 90 to the first terminal 60A with the conductive bonding material SD. Thus, the back surface electrode 96 of the light-receiving element 90 is electrically connected to the back surface electrode 28 of the surface-emitting laser element 20. Further, the surface-emitting laser element 20 and the light-receiving element 90 are mounted on the same terminal front surface 61 of the first terminal 60A. Thus, the surface-emitting laser element 20 and the light-receiving element 90 are mounted on the same plane.

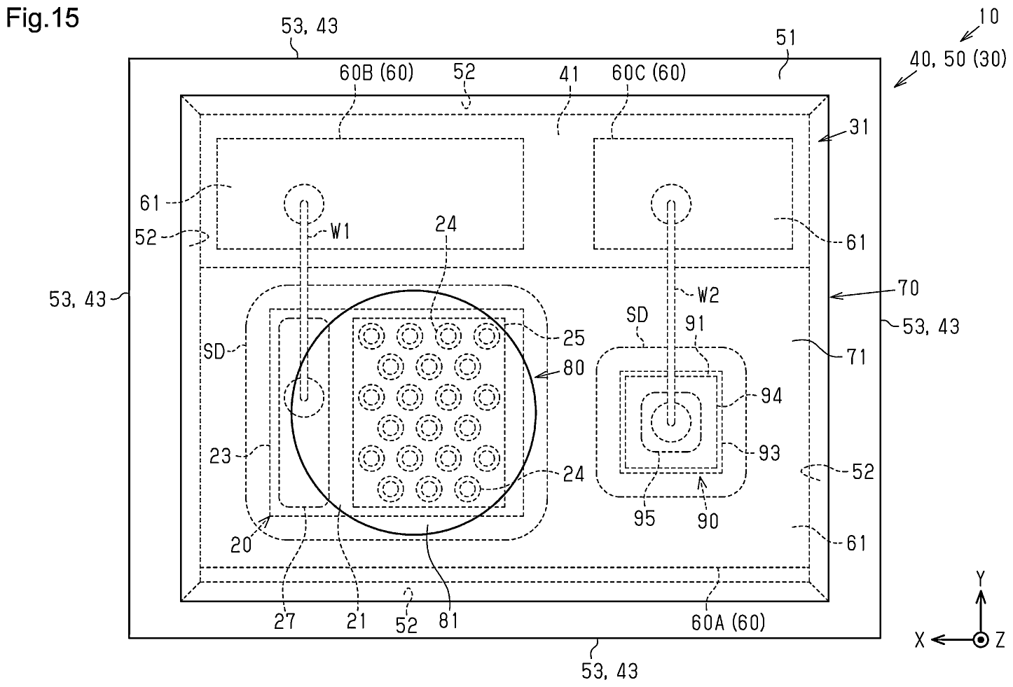

As shown in FIGS. 14 and 15, the semiconductor light emitting device 10 includes the first resin portion 70 and the second resin portion 80.

The first resin portion 70 encapsulates both the surface-emitting laser element 20 and the light-receiving element 90. Further, the first resin portion 70, for example, encapsulates both the first wire W1 and the second wire W2. The first resin portion 70 includes the first resin surface 71. The first resin surface 71 is curved inward and toward the surface-emitting laser element 20. Further, the first resin surface 71 is curved inward and toward the light-receiving element 90. In one example, the parts of the first resin surface 71 facing the surface-emitting laser element 20 and the light-receiving element 90 may include flat surfaces that are orthogonal to the Z-direction.

The first resin portion 70 contains the diffusers 72. The diffusers 72 are fine particles that diffuse light and are dispersed in the first resin portion 70. The diffusers 72 reflect (scatter) light in the first resin portion 70 at the interface of the resin and the diffusers 72 to diffuse light inside the first resin portion 70. The diffusers 72 act to diffuse the laser beam emitted from the element front surface 21 of the surface-emitting laser element 20 in the first resin portion 70 to increase the directivity of the laser beam emitted from the first resin portion 70. The diffusers 72, for example, correspond to the diffusers 72 of the modified example of the semiconductor light emitting device 10 in accordance with the first embodiment shown in FIG. 7.

The light-receiving element 90 receives the part of the laser beam emitted from the element front surface 21 of the surface-emitting laser element 20 that is diffused by the diffusers 72 of the first resin portion 70. A greater compound ratio of the diffusers 72 allows the light-receiving element 90 to readily receive the scattered light.

As shown in FIG. 15, the second resin portion 80 is selectively arranged on the first resin surface 71. The second resin portion 80 is separated from the circumferential edge of the first resin surface 71. That is, the second resin portion 80 is separated from the peripheral wall 50 of the element case 30 in plan view.

The second resin portion 80 is formed on at least part of the first resin surface 71 at a position corresponding to the surface-emitting laser element 20 in the Z-direction. The second resin portion 80 faces all of the light emitters 24 in the surface-emitting laser element 20 in plan view. Further, the second resin portion 80 is separated from the light-receiving element 90 in plan view. More specifically, in plan view, the second resin portion 80 is arranged closer to the surface-emitting laser element 20 than the light-receiving element 90 is. The second resin portion 80 is identical in shape to the second resin portion 80 in the first embodiment shown in FIG. 4.

In one example, the second resin portion 80 is composed of an opaque resin material. In one example, the second resin portion 80 is composed of a resin material having a higher light reflectance than the first resin portion 70. In one example, the second resin portion 80 is formed by a reflector. In the fourth embodiment, the second resin portion 80 is composed of a white resin material. The white resin material may be, for example, an epoxy resin in which titanium oxide or silica is mixed.

With such a structure, the laser beam emitted in the Z-direction from the element front surface 21 of the surface-emitting laser element 20 is reflected by the second resin portion 80. The light-receiving element 90 may receive the part of the beam reflected by the second resin portion 80.

The light-receiving element 90 receives part of the laser beam emitted from the surface-emitting laser element 20. Thus, the semiconductor light emitting device 10 is able to monitor the state of the surface-emitting laser element 20 with the light-receiving element 90. Further, the semiconductor light emitting device 10 can use auto power control (APC) drive that controls the current supplied to the surface-emitting laser element 20 so that the light output of the laser beam emitted from the surface-emitting laser element 20 is constant. In further detail, a controller, which is arranged outside the semiconductor light emitting device 10 and controls the current supplied to the surface-emitting laser element 20, receives signals corresponding to the laser beam of the surface-emitting laser element 20 that is reflected by the second resin portion 80 and received by the light-receiving element 90. The controller is electrically connected to the third terminal 60C to receive signals from the light-receiving element 90. Further, the controller controls the current supplied to the surface-emitting laser element 20 in accordance with the difference of a received signal and a set output value, which is a preset light output. In one example, the controller controls the current supplied to the surface-emitting laser element 20 so that the level of the received signal matches the set output value.

### Advantages of Fourth Embodiment

The semiconductor light emitting device 10 of the fourth embodiment has the advantages described below.
(4-1) The semiconductor light emitting device 10 includes the light-receiving element 90 that is separated from the surface-emitting laser element 20 in the X-direction. The light-receiving element 90 receives the laser beam of the surface-emitting laser element 20.

With this structure, the light output of the laser beam emitted from the surface-emitting laser element 20 can be recognized from the laser beam received by the light-receiving element 90. This allows for control of the light output of the laser beam emitted from the surface-emitting laser element 20.
(4-2) The light emitters 24 are separated from the front surface electrode 27 in the X-direction on the element front surface 21 of the surface-emitting laser element 20. The light-receiving element 90 and the front surface electrode 27 are arranged at opposite sides of the light emitters 24 in the X-direction.

With this structure, the distance in the X-direction can be shortened between the light emitters 24 of the surface-emitting laser element 20 and the light-receiving element 90. This allows the light-receiving element 90 to readily receive the laser beam emitted from the element front surface 21 of the surface-emitting laser element 20.

### Modified Example of Fourth Embodiment

The semiconductor light emitting device 10 of the fourth embodiment may be modified, for example, as described below.

The first resin portion 70 may be modified to have any structure. In one example, the diffusers 72 may be omitted from the first resin portion 70.

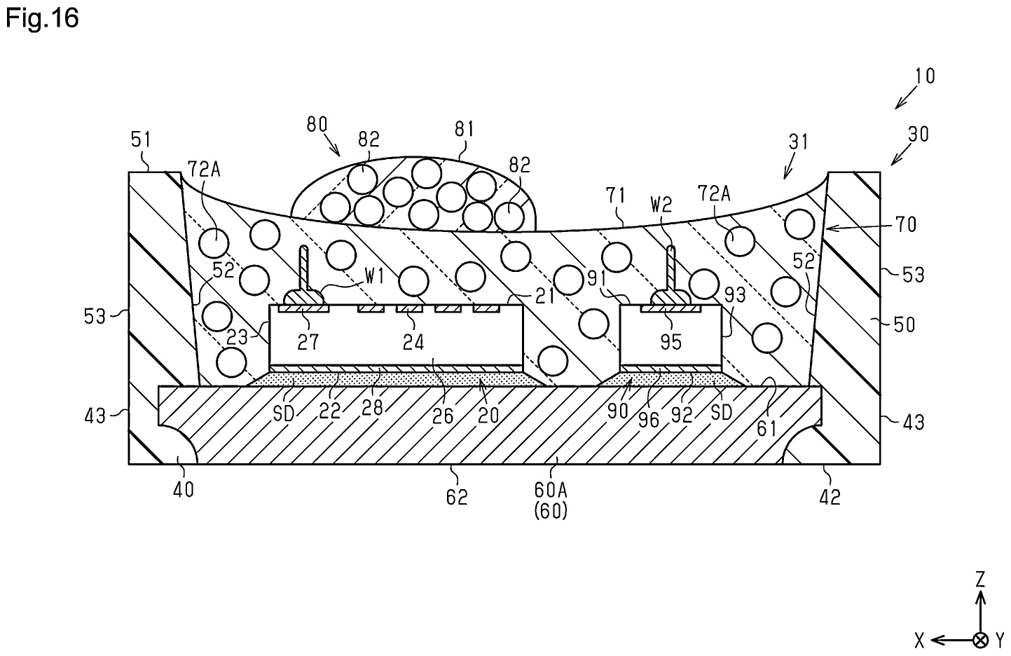

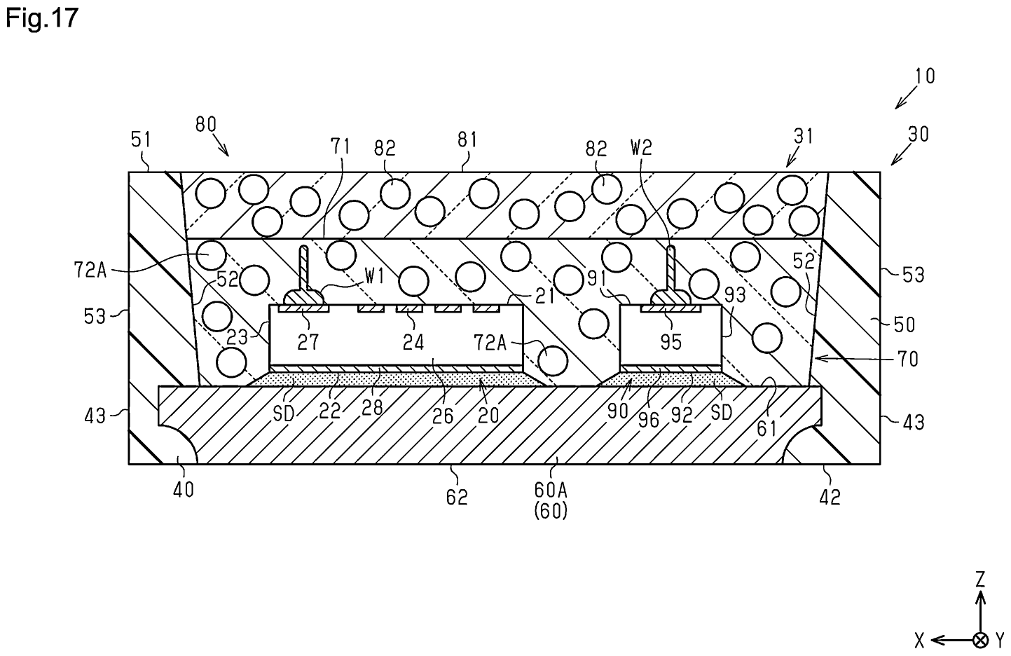

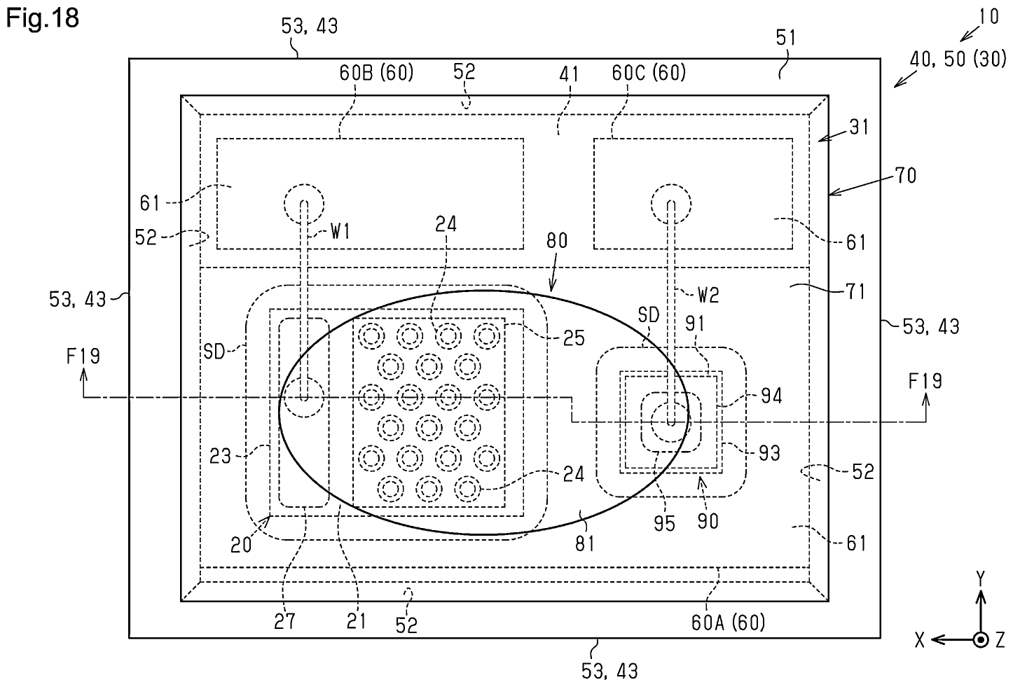

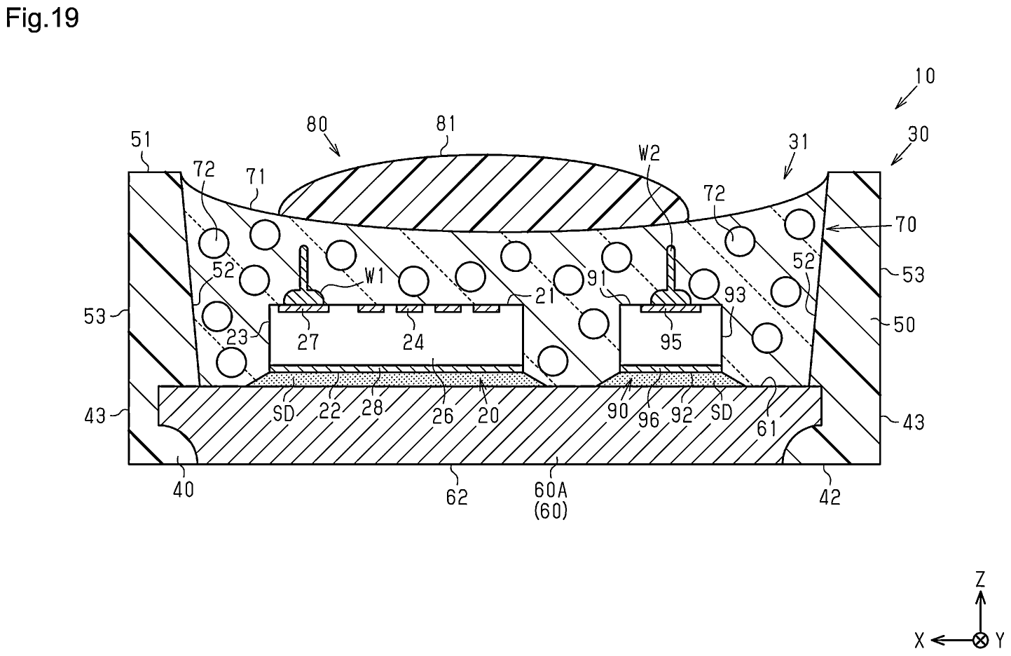

The second resin portion 80 may be modified to have any structure. The semiconductor light emitting device 10 of such modified examples will now be described with reference to FIGS. 16 to 19. FIG. 16, which shows a first modified example of the semiconductor light emitting device 10 in accordance with the fourth embodiment, is a schematic cross-sectional view of the first modified example of the semiconductor light emitting device 10 taken along the same position as line F3-F3 in FIG. 2. FIG. 17, which shows a second modified example of the semiconductor light emitting device 10 in accordance with the fourth embodiment, is a schematic cross-sectional view of the second modified example of the semiconductor light emitting device 10 taken along the same position as line F3-F3 in FIG. 2. FIG. 18 is a schematic plan view of a third modified example of the semiconductor light emitting device 10 in accordance with the fourth embodiment. FIG. 19 is a schematic cross-sectional view showing the structure of the third modified example of the semiconductor light emitting device 10 taken along line F19-F19 in FIG. 18.

As shown in FIG. 16, in the first modified example of the semiconductor light emitting device 10, the first resin portion 70 contains the first diffusers 72A. The first diffusers 72A correspond to the diffusers 72 of the fourth embodiment. Thus, the first resin portion 70 of the semiconductor light emitting device 10 in the first modified example has the same structure as the first resin portion 70 of the fourth embodiment.

The location, shape, and size of the second resin portion 80 are the same as the fourth embodiment. In the same manner as the third embodiment, the second resin portion 80 is composed of a light-transmissive resin material. In one example, the second resin portion 80 is composed of a transparent resin material. In the first modified example, the resin material of the second resin portion 80 is the same as that of the first resin portion 70. Further, in the same manner as the third embodiment, the second resin portion 80 contains the second diffusers 82. The second diffusers 82 have, for example, the same structure and size as the second diffusers 82 of the third embodiment. In the example shown in FIG. 16, the compound ratio of the first diffusers 72A in the first resin portion 70 differs from the compound ratio of the second diffusers 82 in the second resin portion 80. More specifically, the concentration of the second diffusers 82 in the second resin portion 80 is greater than the concentration of the first diffusers 72A in the first resin portion 70. In one example, the concentration of the second diffusers 82 in the second resin portion 80 in percent by weight is greater than that of the first diffusers 72A in the first resin portion 70.

The laser beam emitted from the surface-emitting laser element 20 is diffused by the first diffusers 72A of the first resin portion 70. The laser beam from the first resin portion 70 received by the second resin portion 80 is diffused by the second diffusers 82 of the second resin portion 80. This increases the spreading angle of the laser beam emitted from the semiconductor light emitting device 10.

As shown in FIG. 17, in the second modified example of the semiconductor light emitting device 10, the second resin portion 80 entirely covers the first resin surface 71 of the first resin portion 70. Thus, the second resin portion 80 covers the part of each peripheral wall inner surface 52 of the peripheral wall 50 that projects from the first resin portion 70.

The second resin portion 80 is composed of a light-transmissive resin material. In one example, the second resin portion 80 is composed of a transparent resin material. In the second modified example, the resin material of the second resin portion 80 is the same as that of the first resin portion 70.

The second resin portion 80 contains second diffusers 82. The second diffusers 82 are fine particles that diffuse light and are dispersed in the second resin portion 80. The second diffusers 82 reflect (scatter) light in the second resin portion 80 at the interface of the resin and the second diffusers 82 to diffuse light inside the second resin portion 80. The second diffusers 82 have, for example, the same structure and size as the second diffusers 82 of the third embodiment shown in FIG. 11. The second diffusers 82 act to further diffuse the laser light emitted from the first resin portion 70 in the second resin portion 80 to increase the spreading angle of the laser beam emitted from the second resin portion 80.

As shown in FIGS. 18 and 19, in the third modified example of the semiconductor light emitting device 10, the second resin portion 80 faces at least part of both the surface-emitting laser element 20 and the light-receiving element 90 in plan view. The second resin portion 80 entirely covers the light-emitting region 25 of the surface-emitting laser element 20 in plan view. That is, the second resin portion 80 faces all of the light emitters 24 in plan view. The second resin portion 80 partially covers the light-receiving front surface 91 of the light-receiving element 90 in plan view.

In the example shown in FIG. 19, the second resin portion 80 is composed of an opaque resin material. In one example, the second resin portion 80 is composed of a resin material having a higher light reflectance than the first resin portion 70. That is, the second resin portion 80 is formed by a reflector. In the third modified example, the second resin portion 80 is composed of a white resin material. The white resin material may be, for example, an epoxy resin in which titanium oxide or silica is mixed. In the third modified example of the semiconductor light emitting device 10, the diffusers 72 may be omitted from the first resin portion 70.

The terminals 60 may have any structure. In one example, the terminals 60 may include first to fourth terminals. The first terminal is a terminal on which the surface-emitting laser element 20 is mounted. The first terminal is electrically connected to the back surface electrode 28 of the surface-emitting laser element 20. The second terminal is a terminal on which the light-receiving element 90 is mounted. The second terminal is electrically connected to the back surface electrode 96 of the light-receiving element 90. The third terminal is electrically connected by the first wire W1 to the front surface electrode 27 of the surface-emitting laser element 20. The fourth terminal is electrically connected by the second wire W2 to the front surface electrode 95 of the light-receiving element 90. In another example, the terminals 60 may include a first terminal on which the surface-emitting laser element 20 is mounted, a second terminal on which the light-receiving element 90 is mounted, and a third terminal to which the first wire W1 and the second wire W2 are both connected.

### Modification of Each Embodiment and Modified Examples of Each Embodiment

The above embodiments may be modified as described below. The modified examples described below may be combined as long as there is no technical contradiction.

The resin material of the first resin portion 70 may differ from the resin material of the second resin portion 80.

In the second resin portion 80 entirely covering the first resin surface 71 of the first resin portion 70, the second resin surface 81 may have any shape. In one example, the second resin surface 81 may be curved outward and away from the first resin surface 71 in the Z-direction.

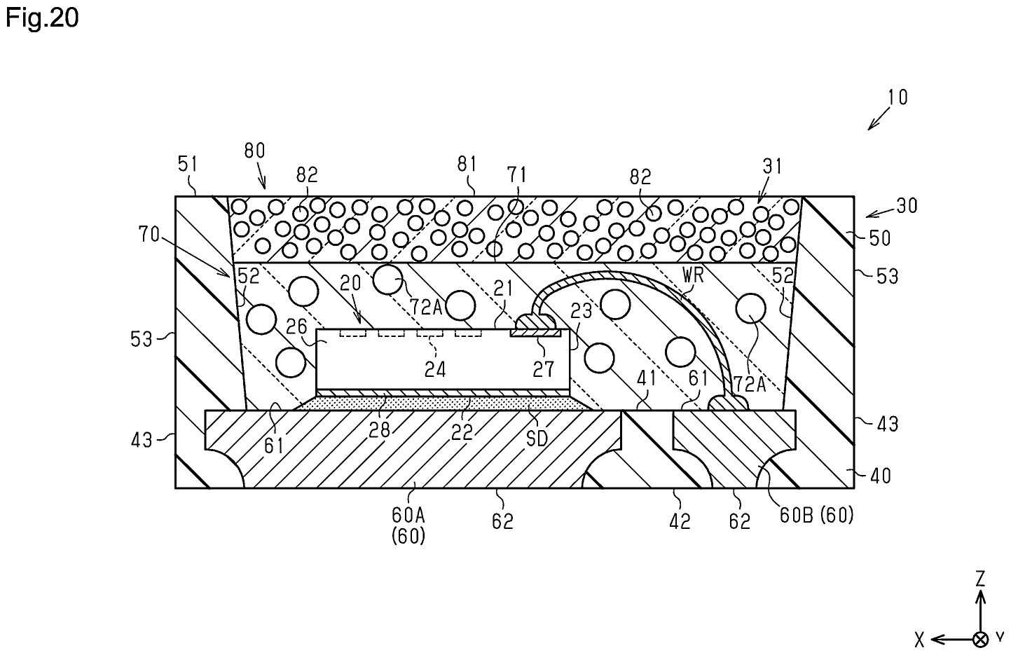

In the semiconductor light emitting device 10 including the first resin portion 70, which contains the first diffusers 72A, and the second resin portion 80, which contains the second diffusers 82, the first diffusers 72A and the second diffusers 82 may each have any particle diameter. In one example, as shown in FIG. 20, the second diffusers 82 have a smaller particle diameter than the first diffusers 72A. In the example shown in FIG. 20, the compound ratio of the first diffusers 72A in the first resin portion 70 differs from the compound ratio of the second diffusers 82 in the second resin portion 80. More specifically, the concentration of the second diffusers 82 in the second resin portion 80 is greater than the concentration of the first diffusers 72A in the first resin portion 70. In one example, the concentration of the second diffusers 82 in the second resin portion 80 in percent by weight is greater than that of the first diffusers 72A in the first resin portion 70.

The second resin portion 80 and the surface-emitting laser element 20 may have any positional relationship. In one example, the second resin portion 80 may be arranged so as not to face some of the light emitters 24 of the surface-emitting laser element 20 in the Z-direction.

The concentration of the first diffusers 72A in the first resin portion 70 and the concentration of the second diffusers 82 in the second resin portion 80 may have any relationship. In one example, the concentration of the second diffusers 82 in the second resin portion 80 may be less than the concentration of the first diffusers 72A in the first resin portion 70. In another example, the concentration of the second diffusers 82 in the second resin portion 80 may be equal to the concentration of the first diffusers 72A in the first resin portion 70.

The second diffusers 82 of the second resin portion 80 may have a greater particle diameter than the first diffusers 72A of the first resin portion 70.

The first diffusers 72A of the first resin portion 70 may be composed of a material differing from that composing the second diffusers 82 of the second resin portion 80.

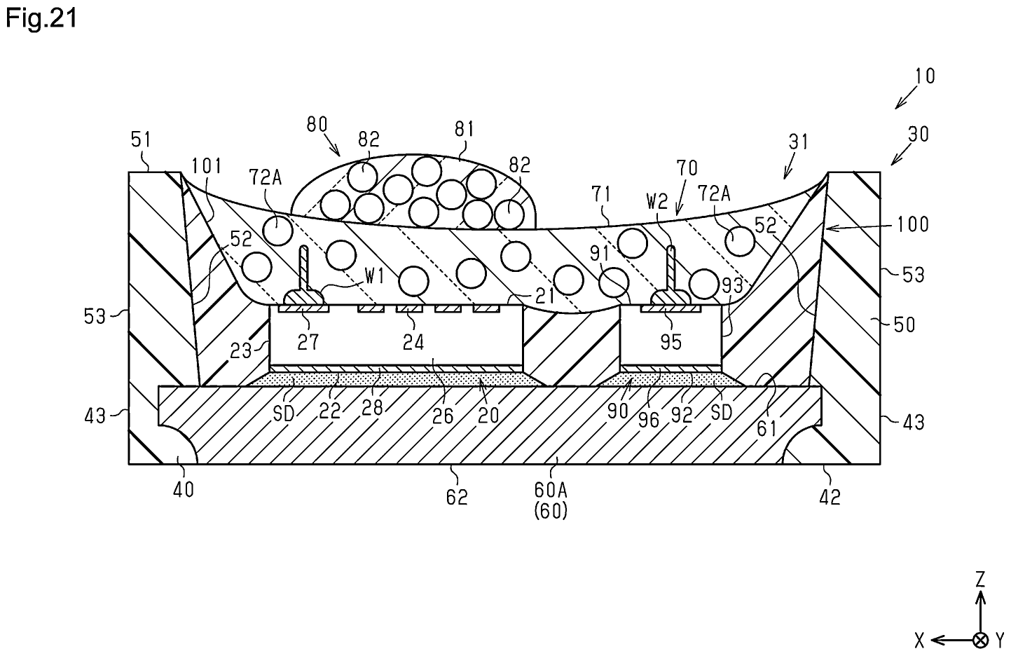

The semiconductor light emitting device 10 may include a reflection body 100 covering at least one of the bottom wall 40 and the peripheral wall 50 in the accommodation cavity 31 of the element case 30. In the example shown in FIG. 21, the reflection body 100 covers both the bottom wall front surface 41 of the bottom wall 40 and the peripheral wall inner surfaces 52 of the peripheral wall 50. In the example shown in FIG. 21, the reflection body 100 covers both the element side surfaces 23 of the surface-emitting laser element 20 and the light-receiving side surface 93 of the light-receiving element 90.

The reflection body 100 is composed of a resin material having a higher light reflectance than the first resin portion 70. In one example, the reflection body 100 may be composed of a resin material having a higher light reflectance than the bottom wall 40 and the peripheral wall 50. In one example, the reflection body 100 is composed of a white resin material. The white resin material may be, for example, an epoxy resin in which titanium oxide or silica is mixed.

The reflection body 100 includes a front surface 101. The front surface 101 of the reflection body 100 is curved inward so that it approaches the peripheral wall surface 51 as it approaches from the surface emitting laser element 20 to the peripheral wall 50. Further, the front surface 101 is curved inward so that it approaches the peripheral wall surface 51 as it approaches from the light-receiving element 90 to the peripheral wall 50. The front surface 101 of the reflection body 100 is curved inward between the surface-emitting laser element 20 and the light-receiving element 90.

The first resin portion 70 is arranged on the front surface 101 of the reflection body 100. In the example shown in FIG. 21, the first resin portion 70 is entirely formed on the front surface 101 of the reflection body 100. The first resin portion 70 covers both the element front surface 21 of the surface-emitting laser element 20 and the light-receiving front surface 91 of the light-receiving element 90. The first resin portion 70 contains the first diffusers 72A. The first diffusers 72A, for example, correspond to the diffusers 72 of the fourth embodiment.

The location, shape, and size of the second resin portion 80 are the same as the fourth embodiment. The second resin portion 80 is composed of a light-transmissive resin material. In one example, the second resin portion 80 is composed of a transparent resin material. The resin material of the second resin portion 80 is the same as that of the first resin portion 70. The second resin portion 80 contains the second diffusers 82. The second diffusers 82 have, for example, the same structure and size as the second diffusers 82 of the third embodiment. In the example shown in FIG. 21, the compound ratio of the first diffusers 72A in the first resin portion 70 differs from the compound ratio of the second diffusers 82 in the second resin portion 80. More specifically, the concentration of the second diffusers 82 in the second resin portion 80 is greater than the concentration of the first diffusers 72A in the first resin portion 70. In one example, the concentration of the second diffusers 82 in the second resin portion 80 in percent by weight is greater than that of the first diffusers 72A in the first resin portion 70.

The second resin portion 80 may be formed by a reflector in the same manner as the second resin portion 80 in the fourth embodiment. In one example, the second resin portion 80 is composed of a white resin material. The white resin material may be, for example, an epoxy resin in which titanium oxide or silica is mixed.

The reflection body 100 may cover the bottom wall 40 without covering the peripheral wall 50. In this case, the peripheral wall 50 is covered by, for example, the first resin portion 70. The reflection body 100 may cover the peripheral wall 50 without covering the bottom wall 40. In this case, the bottom wall 40 is, for example, covered by the first resin portion 70.

The reflection body 100 may partially cover the element side surfaces 23 of the surface-emitting laser element 20. The parts of the element side surfaces 23 that are not covered by the reflection body 100 are covered by the first resin portion 70. The reflection body 100 does not have to cover the element side surfaces 23 of the surface-emitting laser element 20. In this case, the element side surfaces 23 are covered by the first resin portion 70. Further, the reflection body 100 may partially cover the light-receiving side surface 93 of the light-receiving element 90. The part of the light-receiving side surface 93 that is not covered by the reflection body 100 is covered by the first resin portion 70. The reflection body 100 does not have to cover the light-receiving side surface 93 of the light-receiving element 90. In this case, the light-receiving side surface 93 is covered by the first resin portion 70.

The element case 30 may have any structure. In one example, the bottom wall 40 and the peripheral wall 50 are separate. In this case, the bottom wall 40 and the peripheral wall 50 are fixed to each other by an adhesive agent. Further, the semiconductor light emitting device 10 may include a substrate, which serves as the bottom wall 40 of the element case 30, and a case, which is arranged on the substrate and serves as the peripheral wall 50. The surface-emitting laser element 20 is mounted on the substrate. The case surrounds the surface-emitting laser element 20 in plan view. When the semiconductor light emitting device 10 includes the light-receiving element 90, the light-receiving element 90 is mounted on the substrate. The case surrounds both the surface-emitting laser element 20 and the light-receiving element 90 in plan view.

Instead of the terminals 60, the semiconductor light emitting device 10 may include front surface electrodes arranged on the bottom wall front surface 41 of the bottom wall 40. In one example, the front surface electrodes include a first front surface electrode and a second front surface electrode. The first front surface electrode is an electrode on which the surface-emitting laser element 20 is mounted. Thus, the first front surface electrode is electrically connected to the back surface electrode 28 of the surface-emitting laser element 20. The second front surface electrode is electrically connected by the wire WR to the front surface electrode 27 of the surface-emitting laser element 20. When the semiconductor light emitting device 10 includes the light-receiving element 90, the front surface electrodes may include first to third front surface electrodes. The first front surface electrode is an electrode on which the surface-emitting laser element 20 and the light-receiving element 90 are both mounted. Thus, the first front surface electrode is electrically connected to both the back surface electrode 28 of the surface-emitting laser element 20 and the back surface electrode 96 of the light-receiving element 90. The second front surface electrode is electrically connected by the first wire W1 to the front surface electrode 27 of the surface-emitting laser element 20. The third front surface electrode is electrically connected by the second wire W2 to the front surface electrode 95 of the light-receiving element 90.

One or more of the various examples described in this specification may be combined as long as there is no technical contradiction.

In this specification, the word “on” includes the meaning of “above” in addition to the meaning of “on” unless otherwise described in the context. Accordingly, for example, the expression of “first element arranged on second element” may mean that the first element is arranged directly on the second element in one embodiment and mean that the first element is arranged above the second element without contacting the second element in another embodiment. Thus, the word “on” will also allow for a structure in which another element is formed between the first element and the second element.

The Z-direction as referred to in this specification does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction.

### CLAUSES

Technical concepts that can be understood from the present disclosure will now be described. Reference characters used in the above embodiments are added to corresponding elements in the clauses to aid understanding without any intention to impose limitations to these elements. The reference characters are given as examples to aid understanding and not intended to limit elements to the elements denoted by the reference characters.

### [Clause 1]

A semiconductor light emitting device (10), including:
a surface-emitting laser element (20) including an element front surface (21) from which a laser beam is emitted;
a light-transmissive first resin portion (70) that encapsulates the surface-emitting laser element (20) and includes a first resin surface (71); and
a second resin portion (80) that differs from the first resin portion (70) and is at least partially formed on the first resin surface (71) facing the element front surface (21) in a direction (Z-direction) orthogonal to the element front surface (21).

### [Clause 2]

The semiconductor light emitting device according to clause 1, where the second resin portion (80) has a higher light reflectance than the first resin portion (70).

### [Clause 3]

The semiconductor light emitting device according to clause 1 or 2, where the first resin surface (71) is curved inward and toward the surface-emitting laser element (20).

### [Clause 4]

The semiconductor light emitting device according to any one of clauses 1 to 3, where the first resin portion (70) contains a diffuser (72).

### [Clause 5]

The semiconductor light emitting device according to any one of clauses 1 to 3, where
the first resin portion (70) contains a first diffuser (72A),
the second resin portion (80) contains a second diffuser (82), and
a concentration of the second diffuser (82) in the second resin portion (80) is greater than a concentration of the first diffuser (72A) in the first resin portion (70).

### [Clause 6]

The semiconductor light emitting device according to any one of clauses 1 to 3, where
the first resin portion (70) contains a first diffuser (72A),
the second resin portion (80) contains a second diffuser (82), and the second diffuser (82) has a particle diameter that is smaller than that of the first diffuser (72A).

### [Clause 7]

The semiconductor light emitting device according to clause 6, where a concentration of the second diffuser (82) in the second resin portion (80) is greater than a concentration of the first diffuser (72A) in the first resin portion (70).

### [Clause 8]

The semiconductor light emitting device according any one of clauses 5 to 7, where the second resin portion (80) entirely covers the first resin surface (71).

### [Clause 9]

The semiconductor light emitting device according to any one of clauses 1 to 7, where the second resin portion (80) is formed by a reflector.

### [Clause 10]

The semiconductor light emitting device according to clause 9, where the second resin portion (80) is composed of a white resin material serving as the reflector.

### [Clause 11]

The semiconductor light emitting device according to any one of clause 9 or 10, where the second resin portion (80) is selectively arranged on the first resin surface (71).

### [Clause 12]

The semiconductor light emitting device according to clause 11, where the second resin portion (80) is separated from a circumferential edge of the first resin surface (71).

### [Clause 13]

The semiconductor light emitting device according to any one of clauses 1 to 12, where
the second resin portion (80) includes a second resin surface (81), and
the second resin surface (81) is curved outward and away from the first resin surface (71) in the direction (Z-direction) orthogonal to the element front surface (21).

### [Clause 14]

The semiconductor light emitting device according to any one of clauses 1 to 13, where
the surface-emitting laser element (20) includes light emitters (24) arranged in the element front surface (21), and
the second resin portion (80) faces all of the light emitters (24) as viewed in the direction (Z-direction) orthogonal to the element front surface (21).

### [Clause 15]

The semiconductor light emitting device according to any one of clauses 1 to 14, further including a light-receiving element (90) configured to receive a laser beam of the surface-emitting laser element (20) and separated from the surface-emitting laser element (20) in a first direction (X-direction) that intersects the direction (Z-direction) orthogonal to the element front surface (21).

### [Clause 16]

The semiconductor light emitting device according to clause 15, where the first resin portion (70) encapsulates both the surface-emitting laser element (20) and the light-receiving element (90).

### [Clause 17]

The semiconductor light emitting device according to clause 15 or 16, where the second resin portion (80) faces at least part of both the surface-emitting laser element (20) and the light-receiving element (90) as viewed in the direction (Z-direction) orthogonal to the element front surface (21).

### [Clause 18]

The semiconductor light emitting device according to any one of clauses 1 to 17, further including:
an element case (30) including a bottom wall (40) on which the surface-emitting laser element (20) is arranged, and a peripheral wall (50) surrounding the surface-emitting laser element (20) as viewed in the direction (Z-direction) orthogonal to the element front surface (21), where
the bottom wall (40) and the peripheral wall (50) define an accommodation cavity (31) that accommodates the surface-emitting laser element (20) and opens in a direction the element front surface (21) is facing, and
the first resin portion (70) is in contact with both the bottom wall (40) and the peripheral wall (50).

### [Clause 19]

The semiconductor light emitting device according to clause 18, further including:
a terminal (60) extending through the bottom wall (40), where the terminal (60) includes
   a terminal front surface (61) on which the surface-emitting laser element (20) is mounted, and
   a terminal back surface (62) facing a direction opposite the terminal front surface (61) and exposed from the bottom wall (40).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

1. A semiconductor light emitting device, comprising:
a surface-emitting laser element including an element front surface from which a laser beam is emitted;
a light-transmissive first resin portion that encapsulates the surface-emitting laser element and includes a first resin surface; and
a second resin portion that differs from the first resin portion and is at least partially formed on the first resin surface facing the element front surface in a direction orthogonal to the element front surface.

2. The semiconductor light emitting device according to claim 1, wherein the second resin portion has a higher light reflectance than the first resin portion.

3. The semiconductor light emitting device according to claim 1, wherein the first resin surface is curved inward and toward the surface-emitting laser element.

4. The semiconductor light emitting device according to claim 1, wherein the first resin portion contains a diffuser.

5. The semiconductor light emitting device according to claim 1, wherein
the first resin portion contains a first diffuser,
the second resin portion contains a second diffuser, and
a concentration of the second diffuser in the second resin portion is greater than a concentration of the first diffuser in the first resin portion.

6. The semiconductor light emitting device according to claim 1, wherein
the first resin portion contains a first diffuser,
the second resin portion contains a second diffuser, and
the second diffuser has a particle diameter that is smaller than that of the first diffuser.

7. The semiconductor light emitting device according to claim 6, wherein a concentration of the second diffuser in the second resin portion is greater than a concentration of the first diffuser in the first resin portion.

8. The semiconductor light emitting device according to claim 5, wherein
the second resin portion entirely covers the first resin surface.

9. The semiconductor light emitting device according to claim 1, wherein
the second resin portion is formed by a reflector.

10. The semiconductor light emitting device according to claim 9, wherein
the second resin portion is composed of a white resin material serving as the reflector.

11. The semiconductor light emitting device according to claim 9, wherein
the second resin portion is selectively arranged on the first resin surface.

12. The semiconductor light emitting device according to claim 11, wherein
the second resin portion is separated from a circumferential edge of the first resin surface.

13. The semiconductor light emitting device according to claim 1, wherein
the second resin portion includes a second resin surface, and
the second resin surface is curved outward and away from the first resin surface in the direction orthogonal to the element front surface.

14. The semiconductor light emitting device according to claim 1, wherein
the surface-emitting laser element includes light emitters arranged in the element front surface, and
the second resin portion faces all of the light emitters as viewed in the direction orthogonal to the element front surface.

15. The semiconductor light emitting device according to claim 1, further comprising a light-receiving element configured to receive a laser beam of the surface-emitting laser element and separated from the surface-emitting laser element in a first direction that intersects the direction orthogonal to the element front surface.

16. The semiconductor light emitting device according to claim 15, wherein the first resin portion encapsulates both the surface-emitting laser element and the light-receiving element.

17. The semiconductor light emitting device according to claim 15, wherein the second resin portion faces at least part of both the surface-emitting laser element and the light-receiving element as viewed in the direction orthogonal to the element front surface.

18. The semiconductor light emitting device according to claim 1, further comprising:
an element case including a bottom wall on which the surface-emitting laser element is arranged, and a peripheral wall surrounding the surface-emitting laser element as viewed in the direction orthogonal to the element front surface, wherein
the bottom wall and the peripheral wall define an accommodation cavity that accommodates the surface-emitting laser element and opens in a direction the element front surface is facing, and
the first resin portion is in contact with both the bottom wall and the peripheral wall.

19. The semiconductor light emitting device according to claim 18, further comprising:
a terminal extending through the bottom wall, wherein the terminal includes
a terminal front surface on which the surface-emitting laser element is mounted, and
a terminal back surface facing a direction opposite the terminal front surface and exposed from the bottom wall.
